(19) United States
(12) Patent Application Publication
(10) Pub. No.: US 2023/0053354 A1
(43) Pub. Date: Feb. 23, 2023

(54) Determining Beam Correspondence Parameters

(71) Applicant: Fraunhofer-Gesellschaft zur Foerderung der angewandten Forschung e.V., Munich (DE)

(72) Inventors: Paul Simon Holt LEATHER, Berlin-Schlachtensee (DE); Thomas HAUSTEIN, Berlin (DE)

(21) Appl. No.: 17/961,320

(22) Filed: Oct. 6, 2022

Related U.S. Application Data
(63) Continuation of application No. PCT/EP2021/059192, filed on Apr. 8, 2021.

(30) Foreign Application Priority Data
Apr. 9, 2020 (EP) 20169151.6

(51) Int. Cl. H04B 17/309; G01R 29/10; H04B 17/00

(52) U.S. Cl. CPC H04B 17/309; G01R 29/10; H04B 17/0085

(57) ABSTRACT

A method for determining a beam correspondence parameter of a device under test includes arranging the device under test within a measurement environment to allow an exchange of a wireless signal with the device under test. The method generating a first beam with the measurement environment for the exchange of the wireless signaland causing causing the DUT to generate, by using an antenna arrangement of the DUT, a second beam, to form a beam pair with the first beam, the beam pair including a TX beam and an RX beam and to generate a third beam corresponding to the second beam. The method includes determining the beam correspondence parameter for the beam pair using characterizing the second beam and a measurement characterizing the third beam.

### CROSS-REFERENCES TO RELATED APPLICATIONS

This application is a continuation of copending International Application No. PCT/EP2021/059192, filed Apr. 8, 2021, which is incorporated herein by reference in its entirety, and additionally claims priority from European Application No. EP EP20169151.6, filed Apr. 9, 2020, which is incorporated herein by reference in its entirety.

### BACKGROUND OF THE INVENTION

The present invention relates to a method, to measurement environments and to a node for a measurement environment that allow for determining a beam correspondence parameter of a device to be operated in wireless communication networks. The present invention further relates to apparatus and procedures for pattern assessment.

Multiple-input and multiple-output (MIMO) techniques have been used in mobile radio communications since the advent of fourth generation (4G) systems. MIMO is also used in 5G systems and is expected to be used in systems beyond 5G including, for example, 6G. In its simplest form, and considering a paired communication only, one side of the MIMO link prepares and distributes (or multiplexes) a variety of signals for transmission while at the other side or end of the MIMO link, the multiplicity of received signals is collected and combined (demultiplexed). Thus, each MIMO-enabled networking device has to be equipped with a plurality of transmission chains and reception chains wherein each chain comprises antennas, radios and further signal processing functions.

### SUMMARY

An embodiment may have a computer-implemented method for determining a beam correspondence parameter of a device under test (DUT), the method comprising: arranging the DUT within a measurement environment to allow an exchange of a wireless signal with the DUT; generating a first beam with the measurement environment for the exchange of the wireless signal; causing the DUT to generate, by using an antenna arrangement of the DUT, a second beam, to form a beam pair with the first beam, the beam pair comprising a TX beam and an RX beam and to generate a third beam corresponding to the second beam; determining the beam correspondence parameter for the second beam and the third beam using a measurement characterizing the second beam and a measurement characterizing the third beam.

Another embodiment may have a computer implemented method for determining a phase centre of an antenna arrangement of a DUT, comprising: causing the DUT to generate a beam with the antenna arrangement; causing the DUT to lock or maintain at least a part of the beam; measuring the beam for a plurality of relative directions with respect to the DUT to acquire measurement results; and evaluating the measurement results to determine the phase centre.

Another embodiment may have a measurement environment configured for implementing the computer implemented methods according to the invention.

Another embodiment may have a node for a measurement environment comprising: an interface configured for exchanging a wired signal and an antenna arrangement; and wherein the node is configured for providing the wired signal based on a wireless signal received with the antenna arrangement and for RX-beamforming for receiving the wireless signal; and/or for providing the wired signal to the antenna arrangement for a transmission based on the wired signal received with the interface and wherein the node is configured for TX-beamforming for transmitting the wireless signal.

Another embodiment may have a measurement environment comprising a plurality of nodes according to the invention.

Another embodiment may have a measurement environment comprising a plurality of nodes, each node configured for receiving a signal from the DUT and/or transmitting a signal to the DUT, wherein the measurement environment is adapted to implement a virtual link antenna arrangement using the plurality of nodes.

The inventors have found that by causing an apparatus to generate a beam that forms a beam pair together with a beam of a measurement environment, the beam caused by the apparatus may be evaluated in view of the beam correspondence, i.e., in view of how precisely the apparatus may form its beam so as to correspond to the beam of the measurement environment. This allows to provide for a measurement environment and for a method to evaluate an apparatus so as to measure the performance of wireless devices by providing for a configurable and adjustable test environment/test procedure.

According to an embodiment, a method for determining a beam correspondence parameter of a device under test (DUT) comprises arranging the DUT within a measurement environment to allow an exchange of a wireless signal with the DUT. The method comprises generating a first beam with the measurement environment for the exchange of the wireless signal and causing the DUT to generate, by using an antenna arrangement of the DUT, a second beam, to form a beam pair with the first beam, the beam pair comprising a TX beam and an RX beam and to generate a third beam corresponding to the second beam; It is to be noted that the DUT may respond with the third to a beam that is generated with the measurement environment. Alternatively, or in addition, the measurement environment may respond to a beam that is generated with the DUT such that the DUT forms the third beam as an RX beam. The method comprises determining the beam correspondence parameter for the second beam and the third beam using a measurement characterizing the second beam and a measurement characterizing the third beam.

According to an embodiment, a measurement environment is configured for implementing such a method.

According to an embodiment, a node for a measurement environment comprises an interface configured for exchanging a wired signal and an antenna arrangement. The node is configured for providing the wired signal based on a wireless signal received with the antenna arrangement and for RX-beamforming for receiving the wireless signal. Alternatively, or in addition, the node is configured for providing the wired signal to the antenna arrangement for a transmission based on the wired signal received with the interface and wherein the node is configured for TX-beamforming for transmitting the wireless signal. By providing a measurement environment with the capability of RX-beamforming and TX-beamforming, respectively, very flexible measurement environments may be generated.

Further embodiments provide for a measurement environment having a plurality of such nodes.

Another embodiment relates to a computer-readable digital storage medium, a computer program respectively for implementing an invented method.

### BRIEF DESCRIPTION OF THE DRAWINGS

Embodiments of the present invention will be detailed subsequently referring to the appended drawings, in which:

FIG. 1 shows a schematic flow chart of a method according to an embodiment;

FIG. 2a shows a schematic block diagram of a measurement environment according to an embodiment;

FIG. 2b shows a schematic top view of an arrangement of the DUT in the measurement environment of FIG. 2a according to an embodiment to illustrate the beam correspondence;

FIG. 2c shows a schematic illustration of the arrangement of FIG. 2b together with a possible signal flow between the measurement environment and the DUT according to an embodiment;

FIG. 2d shows a schematic illustration of a possible signal flow in which the DUT activates the measurement environment according to an embodiment;

FIG. 3 shows a schematic illustration of a Buckyball structure according to an embodiment;

FIGS. 4a-d show schematic block diagrams of a nodes for a measurement environment, and/or the Buckyball structure, according to an embodiment;

FIGS. 5a-d show schematic block diagrams of further nodes that may implement a node of a measurement system and/or of a Buckyball structure, according to an embodiment;

FIG. 6 shows a schematic flow of a method according to an embodiment which may be executed for using an internal parameter of the DUT;

FIG. 7 shows a schematic flow chart of a method according to an embodiment that may be executed additionally or as an alternative to method of FIG. 6;

FIGS. 8a-b show an example of simplified beam patterns producible by a multibeam antenna arrangement created by a communication device according to embodiments;

FIG. 9 shows an example of beam pairing between two devices according to an embodiment, having a line-of-sight path between;

FIG. 10 shows an example of beam pairing between devices according to an embodiment, having a non-line-of-sight path between;

FIG. 11 shows a schematic view on devices of FIG. 9 using an additional non-line-of-sight path based on reflections on reflective object according to an embodiment;

FIG. 12 shows a schematic diagram illustrating an example expanding the scenario of

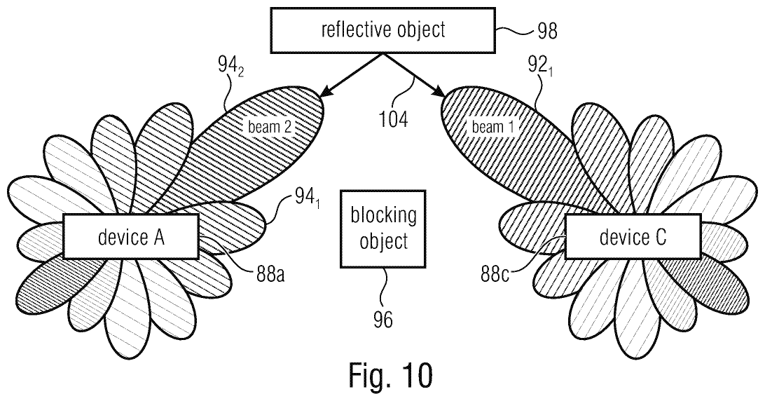

FIG. 10 in which a second reflective object allows for a second non-line-of-sight path according to an embodiment;

FIG. 13 shows an example scenario of two devices providing for two TX-RX beam pairs between devices according to an embodiment;

FIG. 14 shows an example scenario of two TX-RX beam pairs comprising a line-of-sight component and a non-line-of-sight component according to an embodiment;

FIG. 15 shows an example scenario of three TX-RX beam pairs between devices according to an embodiment

FIG. 16 shows an example scenario in which transmission and reception is inverted when compared to FIG. 15 according to an embodiment; FIG. 17 shows a schematic top view of a compact antenna test range (CATR) according to an embodiment; and

FIG. 18 shows a mobile CATR having two sub-reflectors and one main reflector according to an embodiment.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more thorough explanation of embodiments of the present invention. However, it will be apparent to those skilled in the art that embodiments of the present invention may be practiced without these specific details. In other instances, well known structures and devices are shown in block diagram form rather than in detail in order to avoid obscuring embodiments of the present invention. In addition, features of the different embodiments described hereinafter may be combined with each other, unless specifically noted otherwise.

Embodiments described herein relate to antenna radiation patterns or beam patterns that are formed by a device. Such antenna radiation patterns may be transmission radiation patterns and/or reception radiation patterns, i.e., spatial patterns or advantageous directions for transmission and/or reception of a signal. Explanations given herein may relate, thus, to RX beams for beam patterns indicating a reception radiation pattern. Another description is given in connection with TX beams for beam patterns indicating a transmission radiation pattern. RX beam patterns and TX beam patterns may comprise a main lobe (optionally additional main lobes) and one or more side lobes. Between two adjacent lobes a so-called null may be arranged. As described in connection with the millimetre-wave spectrum, the use of millimetre-wave frequencies creates a paradigm change for cellular radio networks as the principle of coverage may move away from that of cell coverage to that of beam coverage instead.

At least some of the embodiments described herein are explained in connection with determining a beam correspondence which is a correspondence between a TX beam and an RX beam. For example, the TX beam may be selected by a device, e.g., a DUT, responsive or based on an RX beam that is used, adapted, generated or implemented to receive a signal from another device. For example, the RX beam may be directed towards a path along which the signal arrives from the other node and a corresponding TX beam may be selected and/or generated to the origin of the received signal, which may include to use a same or a different path. Thereby a RX beam pattern is generated and a TX beam pattern is generated, together forming a beam pair, the beams generated at different entities. Such embodiments may be described by illustrating, for simplicity only, a single lobe which may be a main lobe or a side lobe.

The beam correspondence may, in contrast, relate to beams generated at a same entity. Although the beam correspondence is described so as to relate to a single lobe only, this does not exclude so as to select corresponding beams by considering also additional lobes, i.e., at least two lobes such as a main lobe and a side lobe of a TX beam pattern as well as an RX beam pattern.

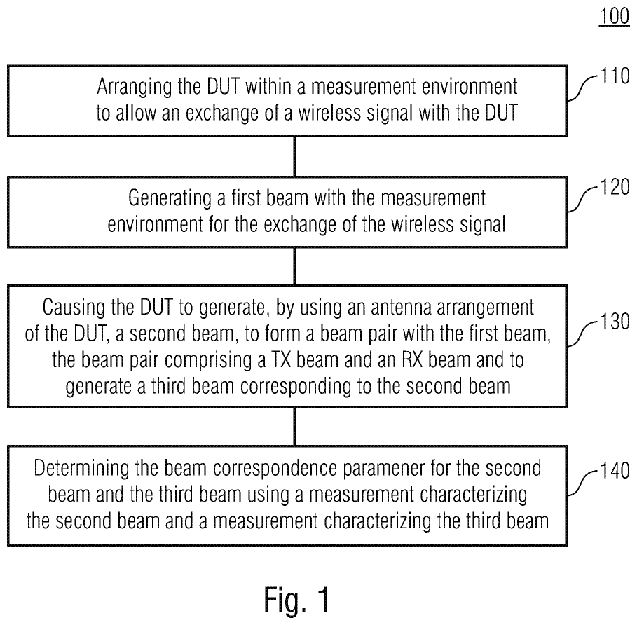

FIG. 1 shows a schematic flow chart of a method 100 according to an embodiment. Method 100 may be implemented for determining a beam correspondence parameter of a device under test (DUT). A beam correspondence parameter may be understood as a parameter or measure for correspondence of beams, i.e., a RX beam corresponding to a TX beam and/or vice versa. Such a beam correspondence parameter may be referred to as a beam parameter, a pattern parameter or the like. A possible information contained in the beam correspondence parameter may be, for example, an ok/not ok (an ok) decision whether the beams fit to each other or not. To provide a high amount of information, the beam correspondence parameter may comprise one or more metrics or relevant values describing a performance indicator, for example, in a binary fashion but also in a way to select between more than two values. In a binary fashion, the indicator may indicate if a conformance test is passed or not passed. The beam correspondence parameter may, alternatively or in addition, include information indicating a result of a performance testing with a measurement/performance metric, e.g., how good the beams fit to each other.

Embodiments are not limited to measurements along a single spatial dimension. In a similar manner, the beam correspondence assessment may be made using more than one spatial dimension, more than one frequency (range), different phase shifts and/or at different polarizations.

Method 100 comprises a step 110 in which the DUT is arranged within a measurement environment to allow an exchange of a wireless signal with the DUT. Examples for such a measurement environment are provided in the following. For example, such a measurement environment may comprise one or more nodes to receive and/or transmit wireless signals such that the wireless signal of step 110 may be transmitted to the DUT and/or received from the DUT.

A step 120 comprises generating a beam with the measurement environment for the exchange of the wireless signal with the DUT. This beam may be a TX beam or an RX beam. For explanation only, the beam of the measurement environment is described as being a TX beam.

The beam generated with the measurement environment may be a beam generated first but may also be a beam that is formed responsive to a beam of the DUT. For example, the beam generated with the measurement environment may be a beam implementing a signal coming from the link antenna, and/or may be a receive beam as a response to a signal transmitted from the link antenna, e.g., when the DUT is a base station; and/or may be a transmit beam from the DUT to the measurement environment or link antenna which is a response to a signal received from the link antenna before.

A step 130 comprises causing generate, by using an antenna arrangement of the DUT, a second beam, to form a beam pair with the first beam, the beam pair comprising a TX beam and an RX beam and to generate a third beam corresponding to the second beam. As described above, the DUT may form an RX beam responsive to a TX beam of the measurement environment and may select an own TX beam so as to correspond, according to a decision or metric of the DUT, to the RX beam.

The beam pair may be understood as a beam pair of RX and TX, forming a unidirectional link between the measurement environment and the DUT or a part of a bidirectional link. The second and third beam are generated in a same device. For example, the DUT may determine a direction from which a signal (TX-beam of the measurement environment) is received, e.g., by determining or trying multiple RX beams (second beam) and selecting the one that fits best according to a metric or decision criterion. I.e., there may occur a deviation between the real TX beam transmitted and an identification at the receiving device, the identification leading to a selection at the receiving device of a TX beam that is aimed to point towards the received beam or to another direction, e.g., a different multipath component/path or the like. Such a procedure may be error prone due to miscalculations and/or limited capabilities at the receiving device to identify the correct direction from which the TX beam to be answered is received and/or limited capabilities in view of spatial resolution of an own TX beam to be formed. Such errors or correspondences may be indicated by a beam correspondence parameter.

For the RX beam or lobe that is considered to be the RX beam or part thereof with the highest performance, i.e., the best RX beam, a corresponding TX beam is selected by the DUT as the third beam and so as to transmit the signal along the same direction from which the RX beam is received or along a direction that is determined by the DUT based on its RX measurements.

For example, the measurement environment may be controlled so as to generate a TX beam and the DUT may be caused in step 130 to cause a suitable RX beam that forms the beam pair with the TX beam of the measurement environment. Alternatively, or in addition, the DUT may generate a TX beam so as to emit a radio signal to the measurement environment and the measurement environment may form a suitable RX beam. Thus, a sequence of step 120 and 130 is not limited so as to execute step 130 after step 120. Alternatively, or in addition, step 120 may be executed simultaneously with step 130 or after step 130.

Method 100 allows for testing different types of apparatus. For example, testing a UE may allow the measurement environment to simulate or emulate a base station that communicates with the DUT. Alternatively, the DUT may be a base station such that the measurement environment implements the part of a UE. Further, in both cases an uplink and/or a downlink behaviour may be tested. That is, the reference to beams generated with the DUT may be adapted to each of those cases.

A step 140 comprises determining the beam correspondence parameter for the set of beams comprising the second beam and the third beam using using a measurement characterizing the second beam and a measurement characterizing the third beam. For example, a first set of at least one measurement taken by/at the measurement environment and a second set of at least one measurement taken by the DUT and a correlation or comparison between the two sets of measurements may be implemented. For example, this may include taking a relative and/or an absolute spatial relationship between DUT and measurement environment into account and/or using temporal markers related to the measurement values. Determining the beam correspondence parameter may relate to a comparison, evaluation, or other types of assessment using the RX beam behaviour or performance or beam pattern with the TX beam pattern, behaviour or performance. As discussed, it may allow to evaluate, how good the beams of the beam pair fit or correspond to each other, e.g., in view of a spatial overlap or the like.

The beam correspondence parameter may but is not limited to a conformance test (passed/not-passed) but also allows to at least include a performance testing with a measurement/performance metric.

For implementing step 140, one or more measurements may be implemented for characterizing the beams of the DUT. For example, the measurements may be performed at a respective receiver side, i.e., at the DUT in view of an RX beam of the DUT and/or at the measurement environment in view of the TX beam of the DUT. The evaluation or comparison, i.e., the determination of the beam correspondence parameter may be performed at any entity, e.g., the measurement environment or a different entity.

This allows to implement, generate or manufacture DUTs, i.e., devices for a use in wireless networks, without forcing the manufacturers for providing access to their interfaces and/or to keep specific implementation details proprietary and/or secret. A DUT may also be evaluated in absence of such knowledge in view of how precisely the DUT may select for a beam pattern to establish at least a part of a link with a communication partner, i.e., to form the beam pair.

Optionally, the method 100 may comprise a pairing of the DUT with the measurement environment, e.g., to set the DUT into a test mode and/or to establish a wireless connection between the measurement environment and the DUT. For example, by implementing a virtual or physical link antenna with the measurement environment, a signal may be generated and transmitted towards the DUT that causes the DUT to respond to this signal by transmitting an answering signal and/or vice versa. Alternatively, or in addition, the pairing may comprise exposing the DUT to a variable or configurable direction of arrival spectrum of multipath components using a link antenna arrangement of the measurement environment that may comprise, as described, a or a multitude of physical and/or virtual link antenna(s). Such a variable exposure may alternatively or in addition be used whilst generating the beam with the measurement environment that forms a part to the beam pair.

A link antenna arrangement may be used to communicate with the DUT during a test procedure, wherein the behaviour of the DUT may be evaluated using nodes of the measurement environment that probe the DUT, i.e., using probes. As will be discussed later, embodiments provide for nodes that may simultaneously or sequentially be used as at least a part of a link antenna arrangement and as a probe.

Embodiments relate to use of a virtual link antenna arrangement as an alternative or in addition to a physical link antenna. A virtual link antenna arrangement may allow to use a single or a combination of nodes to emulate a physical link antenna and, thus to implement a varying property such as polarization, phase, location, power or the like without moving a physical link antenna with respect to the DUT.

The link antenna arrangement may, in view of a virtual link antenna simulate, e.g., by controlling the nodes accordingly, a physical link antenna and a channel characteristic between the measurement environment and the DUT. The virtual link antenna arrangement may allow to emulate a channel condition such as a multipath propagation environment by use of a set of nodes, i.e., the virtual link antenna arrangement may, in addition to the antenna behaviour, also implement a channel behaviour by implementing a respective channel metric. The virtual link antenna may be generated, i.e., the nodes may be controlled so as to emulate or simulate a specific, probably test-specific, physical link antenna.

In other words, similar antenna characteristics to be generated, simulated or obtained by a virtual link antenna may relate to the measurement environment with its virtual link antenna to create a Direction of Arrival (DoA) spectrum and/or to measure a Direction of Departure (DoD) spectrum equivalent to a particular antenna pattern at a base station that went through a radio propagation environment.

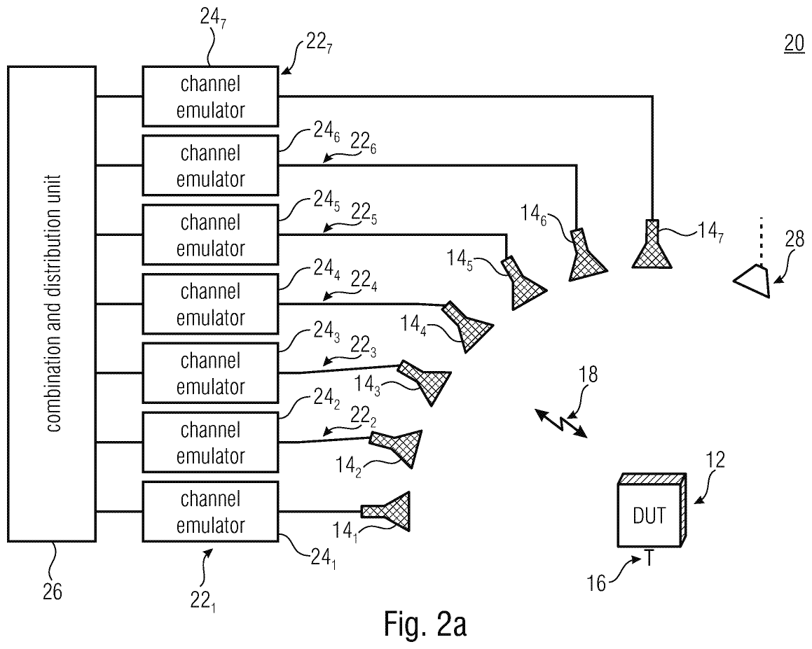

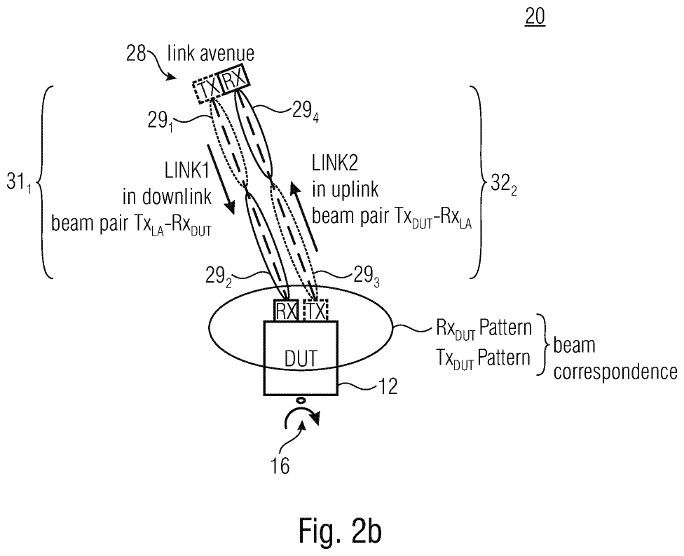

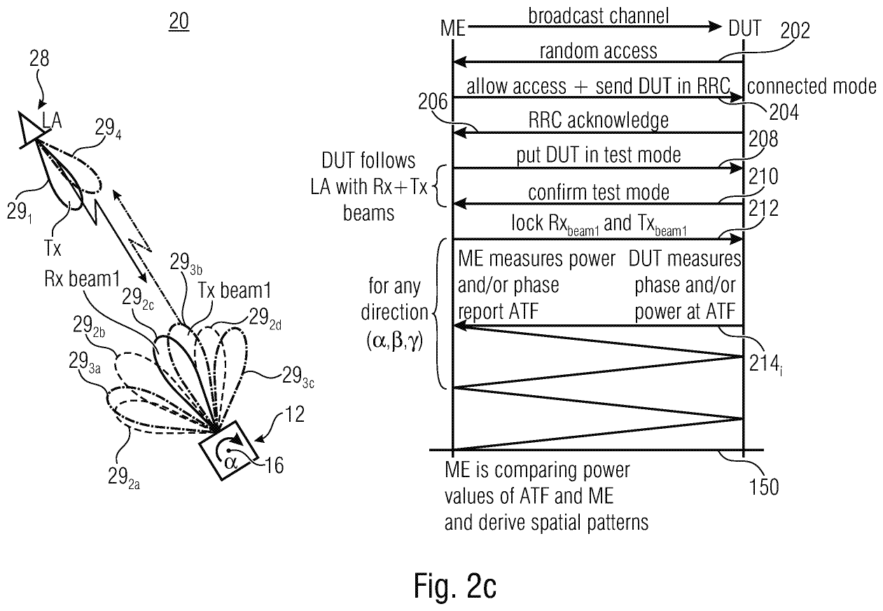

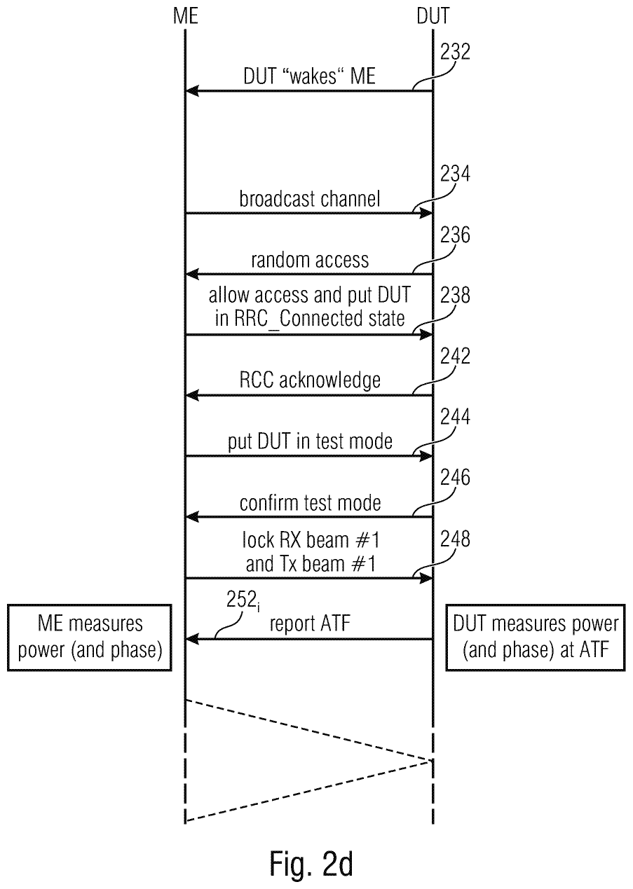

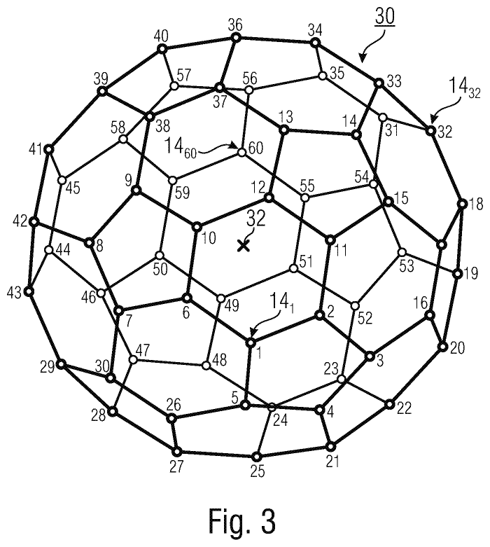

FIG. 2a shows a schematic block diagram of a measurement environment 20 according to an embodiment. The measurement environment 20 is adapted so as to allow an arrangement of a DUT 12, e.g., the DUT being tested by use of method 100. DUT 12 may comprise one or more antenna arrangements, each antenna arrangement being adapted so as to allow beamforming, alone or in combination with other antenna arrangements.

The measurement environment may comprise a plurality of nodes 14₁ to 14₇, wherein a number of nodes 14 may be any suitable number of at least two. The nodes 14₁ to 14₇ may be arranged in any suitable manner to allow measurements for parameters of interest. By way of example, the nodes may be arranged so as to cover at least a part of a sphere along one direction (e.g., azimuth or elevation) or two directions. By rotating or re-positioning the DUT a suitable number of times, a full sphere of the DUT may be measured. Optionally, at least one of the directions may be fully covered by the nodes 14₁ to 14₇, therefore allowing to avoid a replacement of the DUT. One example of an arrangement of the plurality of nodes is to arrange them at least as a part of a Buckyball structure which is explained in connection with FIG. 3. That is, the nodes 14₁ to 14₇ may be arranged as at least a part of the Buckyball structure.

The measurement environment 20 may comprise a DUT holder 16 configured to hold the DUT 12. The DUT holder 16 may be configured for implementing a translatory and/or rotatory movement of the DUT 12. Alternatively, or in addition, the measurement environment 20 may be configured for providing for a relative movement of one or more nodes 14 with respect to the DUT 12. That is, the measurement environment 20 may be configured for implementing a rotatory movement of the plurality of nodes and/or a translatory movement of the plurality of nodes.

The nodes 14₁ to 14₇ may be implemented for receiving and/or transmitting a wireless signal 18 such that the wireless signal 18 may be exchanged between the DUT and the measurement environment 20.

Each of the nodes 14₁ to 14₇ may be part of an individual transmission chain 22₁ to 22₇, each transmission chain 22₁ to 22₇ comprising a channel emulator 24₁ to 24₇ configured for adapting, attenuating or equalizing a signal according to a control signal of a combination and distribution unit (control unit) 26 so as to allow to generate or simulate different channel conditions by use of the different transmission chains 22₁ to 22₇. Although the transmission chains 22₁ to 22₇ are illustrated so as to comprise only a single node 14₁ to 14₇, this does not exclude to control more than one node with a transmission chain, i.e., to connect more than one node to a channel emulator 22₁ to 22₇.

The measurement environment 20 may comprise a link antenna arrangement 28. The link antenna arrangement 28 may be operated so as to simulate a communication partner for the DUT 12 that is considered as a base station or the like, e.g., a communication partner towards the DUT 12 aims to form its RX beam pattern and/or TX beam pattern. The link antenna arrangement 28 may be implemented as a physical link antenna, a virtual link antenna or a combination thereof. For example, the nodes 14 may be used for transmitting respective signals that are considered as the link antenna of a base station at the DUT 12. Alternatively, or in addition, additional or dedicated antennas may be arranged in the measurement environment 20 for such purpose. The link antenna arrangement 28 may, thus, be formed as a virtual antenna arrangement implemented by at least one node 14₁ to 14₇ of the measurement environment. Using more than one node 14₁ to 14₇ may low for simulating varying or different locations of the link antenna and/or different or varying channel conditions between the link antenna 28 and the DUT 12.

In other words, the link antenna arrangement may be a single source antenna or an arrangement of radiation transmitting antenna elements localized or distributed in space and belonging and connected to the measurement environment, e.g., implementing one or a multitude of link antennas. In the context of the Buckyball structure described in connection with FIG. 3, the virtual link antenna can be comprised of many nodes which when being active at least in groups can emulate a multipath environment. Furthermore, embodiments provide an enhanced method allowing to evaluate/determine the enhanced/extended beam correspondence properties of a DUT when two or more base stations/link antennas are involved. This may allow for testing beam correspondence in presence of interference when selecting a beam (e.g., RX) at the DUT and/or measurement environment and/or in order to suppress/avoid/mitigate interference caused by a beam (e.g., TX of the DUT).

The measurement environment 20 may be used for executing methods that are embodiments of the present invention, for example, the method 100.

In other words, FIG. 2a shows an example of a planar multi-probe measurement environment or system. The system comprises a device under test (DUT) and an arrangement of measurement antennas or probes 14, each of which is connected to its own or a shared channel emulator (CE) which in turn is connected to a combination and distribution unit (CDU). As the probes can be used for the purposes of both transmission and reception, a suitable arrangement of one or more CEs together with the appropriate configuration of the CDU allows the DUT to be tested in an effective far field (EFF) or an equivalent near field (ENF) environment. The availability of multiple probes allows multipath propagation channels (MPCs) to be created and, furthermore, using multiple channel emulators, MPCs that emulate the effects of DUT motion (fading), static and dynamic interference or the like. Such dynamic effects can be emulated temporally, spatially and by using combinations of the two. That is, embodied methods, nodes and apparatus allow to test a DUT in an effective far field, an effective near field and/or using multipath propagation channels.

FIG. 2b shows a schematic top view of an arrangement of the DUT 12 in the measurement environment 20. For example, the measurement environment 20 is adapted to generate a beam 29₁, e.g., a TX beam and/or using the link antenna arrangement 28 or other nodes of the measurement environment. The DUT 12 may form an RX beam 29₂ that forms a beam pair 31₁ with the beam 29₁. Upon evaluation of the DUT 12, the DUT 12 may form a TX beam 29₃, the third beam, so as to correspond with the beam 292. The beam 293 may optionally form a second beam pair with a related RX beam 292 of the measurement environment 20. Beam correspondence may be evaluated, e.g., in step 140 by comparing metrics related to beams 29₂ and 29₃.

In view of this example, the third beam 29₃ is created by the DUT, but is evaluated by a measurement done at the measurement environment. For example, the DUT can report about a selected beam or that it maintained a particular (locked) beam, e.g., under the LOCK command. Possibly, the antenna test function (ATF) cannot measure anything to be reported for a TX beam generated with the DUT that provides for suitable value such that the values or results may be obtained at the measurement environment. That is, determining the beam correspondence parameter for the beams formed with the DUT may be based on the antenna test function of the measurement environment and/or the report of the DUT about its results.

FIG. 2c shows a schematic illustration of the arrangement of FIG. 2b together with a possible signal flow between the measurement environment (ME) 20 and the DUT 12. For example, using or simulating a broadcast channel of a wireless communication network, a random access procedure may be executed, see step 202. To set the DUT into a connected mode, a message may be sent to the DUT that indicates an allowance of access to network resources. Such a signal may be sent in step 204 in a RRC (Radio Resource Control) message, followed possibly by a corresponding acknowledgement in a step 206. Such a procedure may be referred to as pairing. The DUT may be set into a test mode, step 208 which may be confirmed in a step 210 by the DUT. In a step 212 the DUT may be instructed to lock and/or maintain beams, i.e., the second and/or the third beam. Until then, the DUT may follow the link antenna 28 in view of a direction of the beam patterns (RX and/or TX) generated. When being fixed, maintained or locked, a relative orientation of the beams with regard to the DUT may be locked such that a movement between the measurement environment 20 and the DUT 12 may lead to beams pointing away from the link antenna arrangement when performing measurements 214ᵢ of power and/or phase or other parameters in i iterations with i being at least one and may differ for a plurality of directions or relative orientations of the DUT 12, for example. Measurements may be performed at the DUT and at the measurement environment, whilst the DUT may report its results.

In step 140, the measurement environment 20 may, for example, compare an amplitude value and/ or a phase value measured at the ATF of the DUT (indicating a reception pattern for iterations i) and at the measurement environment 20 (indicating a transmission pattern of DUT 12 for iterations i) to determine at least a part of the beam correspondence parameter.

For selecting the beam 29₃, a plurality of candidates 29₂ₐ-29_{2d} may be examined by the DUT 12. For example, the candidate 292_{c} may allow for a best reception of the signal transmitted with beam 29₁ and, thus, the DUT may select based on an internal decision, TX beam candidate 29_{3b} as corresponding beam to be generated, e.g., responsive to step 206. Afterwards, when being locked, the relative movement of the DUT 12, e.g., caused with holder 16, may allow for varying reception levels or parameters as an orientation of beam 29_{2c} being selected as second beam varies with regard to beam 29₁. Additionally, by using the measurement environment 20, a pattern and/or other measures related to the beam 29_{3b}, which is also locked may be determined. Such measures may comprise, amongst other things, one or more of a frequency (range), time (slots, slot structure), coding, and/or polarization as well as a phase.

Whilst FIG. 2c illustrates a signal flow graph in which the measurement environment is broadcasting and the DUT responds on the RACH. FIG. 2d shows a scenario in which the measurement environment (ME) (for whatever reason) is, for example, not broadcasting but is awakened or activated by a signal sent from the DUT in a step 232 such that the ME broadcasts in 234. The DUT implements a random access in 236. To set the DUT into a connected mode, a message may be sent to the DUT that indicates an allowance of access to network resources. Such a signal may be sent in step 238 in a RRC (Radio Resource Control) message, followed possibly by a corresponding acknowledgement in a step 242 Again, the DUT may be set into a test mode, step 244 which may be confirmed in a step 246 by the DUT. In a step 248 the DUT may be instructed to lock and/or maintain beams, i.e., a specific RX beam and related TX beam. Measurements 252ᵢ may be performed such that this procedure may incorporate steps 234 to 252ᵢ at least in parts as the corresponding steps 202 to 214ᵢ. After 252ᵢ, step 140 may be executed.

FIG. 3 shows a schematic illustration of a Buckyball structure 30. Such a Buckyball structure may be considered as a structure being a geometric body having vertices that are equally spaced from adjacent vertices (e.g., with respect to three neighbours) and that approximate the surface of a sphere. FIG. 3 shows a schematic illustration of a Buckyball structure having a number of 60 nodes. References [1] to [5] provide examples of over-the-air test and measurement systems in which the distribution of measurement points is discussed. The Buckyball structure being used in embodiments described herein is alluded to in reference [2], whereas a more thorough discussion of its properties is presented in references [4] and [5].

While making reference again to FIG. 2, in order to test and measure the performance of a DUT, a configurable and adjustable test environment is provided to provide a variety and a plurality of suitable stimuli. An additional problem addressed by the embodiments described herein is the measurement of beam correspondence for one and for more than one set of beams, i.e., multiple beam correspondence.

In other words, FIG. 3 shows an example of a three-dimensional arrangement of measurement probes in which the sixty numbered nodes form the vertices of a truncated icosahedron which is also referred to as a Buckyball. The geometry illustrated in the FIG. 3 offers the advantage of uniformly distributing the measurement probes over the surface of an imaginary sphere into which the DUT would be placed at its centre 32. Partial mechanical rotation or rocking of the structure allows spatial oversampling to be performed. Alternatively, for a full Buckyball structure or a full sphere to be implemented, a partial segment of this sphere may be formed by a part of a Buckyball and may be used in a measurement setup, e.g., a hemisphere.

The Buckyball is one particular example of a node distribution on a sphere at constant radius around a centre fulfilling a constant vertices criterion. However, embodiments described herein are not limited to a Buckyball configuration but can also be arranged according to different node distribution schemes, e.g., equiangular node distribution along one or more fixed rotation axis.

Any node of the Buckyball can be used as a transmitter, a receiver, a transceiver and/or a combination thereof. In other words, the nodes can be used/arranged for different purposes. For example, a specific share of the nodes, e.g., a quarter, a half, a third or the like, e.g., 30, can be used for transmission and the remaining nodes (or a share thereof, e.g., 30) can be used for reception. In a different example, 60 nodes can be used for reception and 15 nodes can be used for transmission. In yet another example, 30 nodes can be used for reception and 15 nodes can be used for transmission. However, any number of nodes may be implemented and any node may, individually, be configured for reception, transmission and/or transceiving operation.

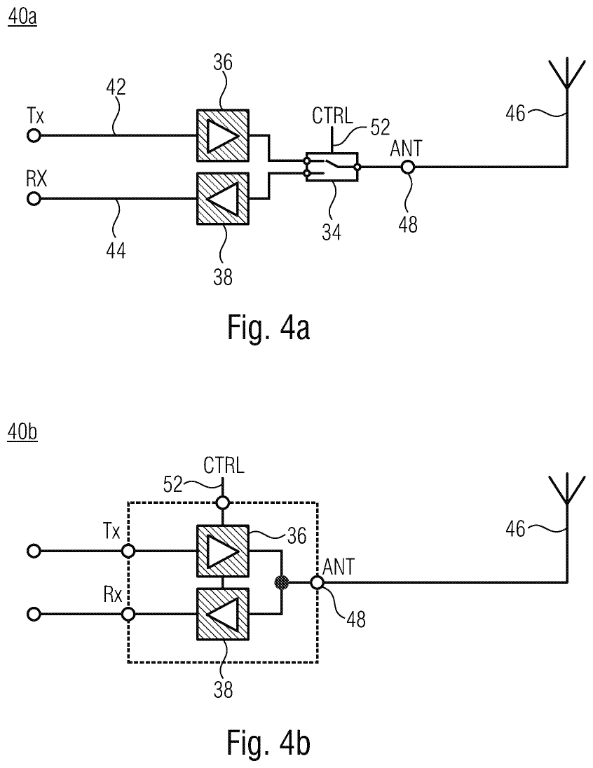

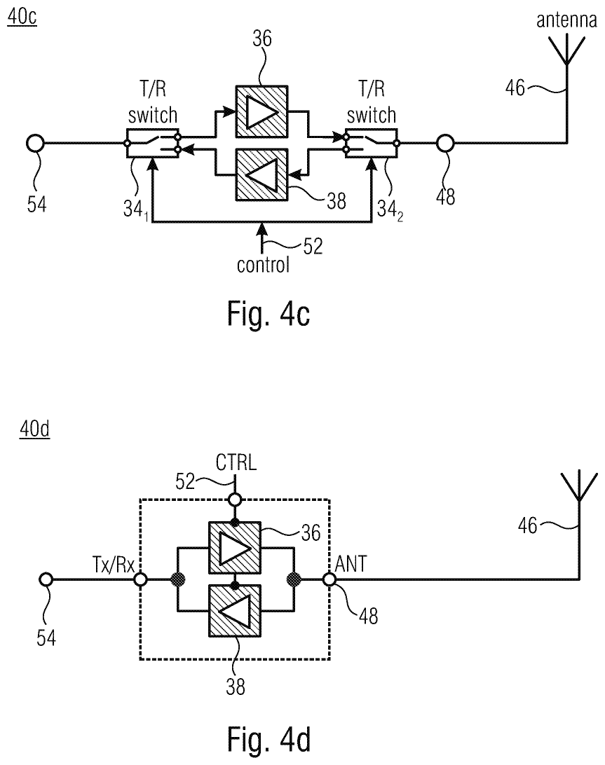

FIG. 4a shows a schematic block diagram of a node 40a that may be used as node 14 in the measurement environment 20 and/or the Buckyball structure 30. A switch 34 may be used for switching the node 40a between a transmission mode and a reception mode, wherein a TX-amplifier 36 and an RX-amplifier 38 may be used for amplifying a TX-signal 42 to be transmitted with an antenna connected at an antenna part 48 (ANT), for amplifying a signal received with the antenna 46 so as to obtain an RX signal 44. A control signal 52 (CTRL) may be used so as to control the switch 34 in view of its operation or switching state.

In other words, FIG. 4a shows a schematic block diagram of a switch being used to route transmission signals via a transmitter to the antenna or, alternatively, reception signals via a receiver from the antenna.

FIG. 4b shows a schematic block diagram of a node 40b that may implement one or more nodes 14₁ to 14₇ of the measurement environment 20 and/or a node of the Buckyball structure 30. When compared to the node 40a, the switch 34 may be replaced with a common connection and the control signal 52 may be used to control the TX amplifier 36 and the RX amplifier 38 based on the actual requirements, e.g., based on the requirement of transmitting a signal or receiving a signal. For example, only one of the amplifiers 36 and 38 may be controlled to be operable/active at a time.

FIG. 4c shows a schematic block diagram of a node 40c that may be used as a node 14 in the measurement environment 20 and/or the Buckyball structure 30. When compared to the node 40a, the node 40c comprises two switches 34₁ and 34₂ that may be controlled based on the control signal 52 in view of a transmission/reception mode such that both switches 34₁ and 34₂ may be referred to as T/R switches. The node 40c comprises a TX/RX-port 54 comprising, when compared to the nodes 40a and 40b, a common input/output. Based on the control signal 52 a TX-path may be provided when connecting the TX/RX-port with the TX amplifier 36 and by connecting the antenna 46 with the TX amplifier 36. In a different mode of operation, the TX/RX-port 54 and the antenna 46 may both be connected to the RX-amplifier 38 based on the control signal 52.

In other words, FIG. 4c shows a modified form of FIG. 4a in which the common connections are used for switches at both the inputs and outputs of the radio transmitter and receiver.

FIG. 4d shows a schematic block diagram of a node 40d that may implement one or more nodes 14 of the measurement environment 20 and/or of the Buckyball structure 30. When compared to the node 40b, the node 40d comprises a common TX/RX-port 54 as described in connection with node 40c.

In other words, FIG. 4d shows an extension of FIG. 4b and FIG. 4c in which one common connection is used at the input of the radio transmitter and the output of the radio receiver.

A second common connection is used at the output of the transmitter and the input of the radio receiver. The radio circuits are controlled in a simplex fashion (only one device is operable at a time).

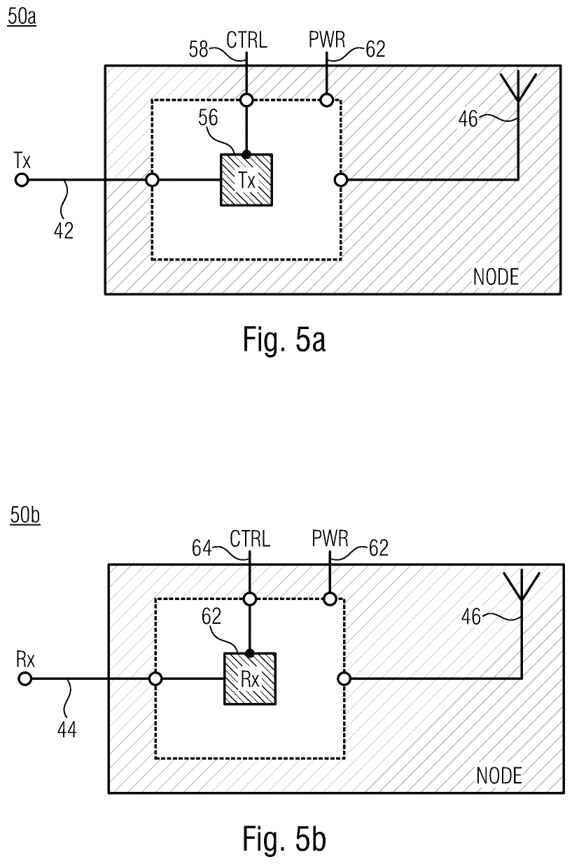

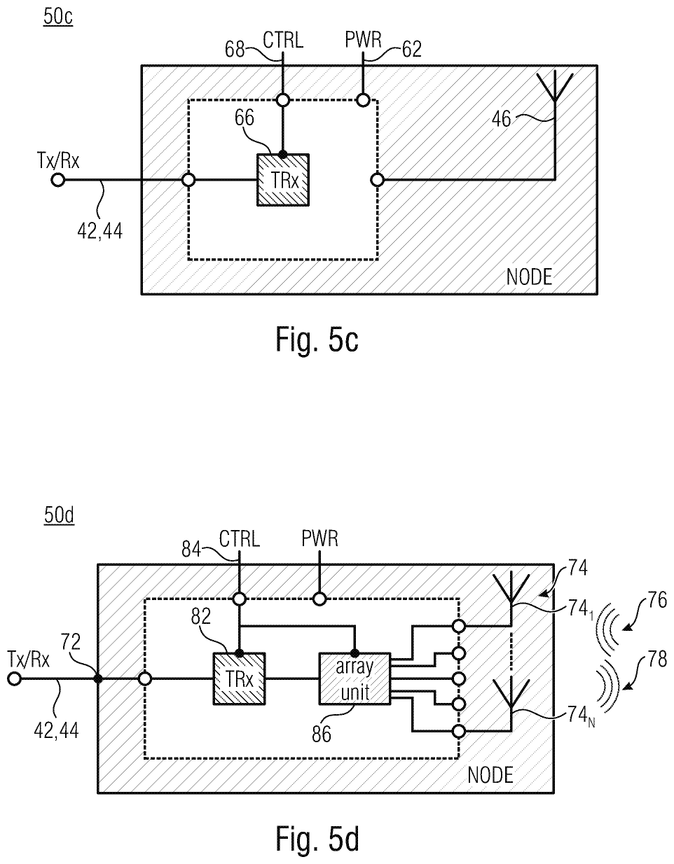

FIG. 5a shows a schematic block diagram of a node 50a that may implement a node of the measurement system 20 and/or of the Buckyball structure 30. The node 50a may be considered as a transmission node and may comprise a transmitter 56 to which the RX-signal 42 may be supplied and which may be controlled by a control signal 58. A further power signal 62 (PWR) may be used for supplying electrical power. In other words, FIG. 5a shows a schematic block diagram of an example node of a Buckyball being used for transmission purposes only. The node comprises at least one transmitter and an antenna.

FIG. 5b shows a schematic block diagram of a node 50b being adapted as a receiver node. When compared to the node 50a, the node 50b comprises a receiver 62 being connected to the antenna 46 and being controllable by use of an RX-control signal 64 so as to provide the RX-signal 44. That is, node 50b forms a compliment to node 50a as being a receiver instead of a transmitter. In other words, FIG. 5b shows an example showing one node of a Buckyball being used for reception purposes only. The node comprises at least a receiver and an antenna.

FIG. 5c shows a schematic block diagram of a node 50c that combines transmitter functionality of node 50a and receiver functionality of node 50b by comprising a transceiver (TRx) 66 being controllable by use of a transceiver control signal 68. Based on an operation mode, for example, half-duplex or full-duplex, the transceiver 66 may receive and/or provide for signals 42 and 44 by use of the antenna 46. In other words, FIG. 4c shows an example showing one node of a Buckyball being used for either transmission or reception purposes. The node 50c comprises at least a transceiver and an antenna.

As described for nodes 50a, 50b, 50c and 50d, also nodes 50a, 50b and/or 50c may be used as a node of the measurement environment 20 and/or of the Buckyball structure 30.

The nodes thereof may be formed equally or differently as described in connection with the Buckyball structure 30 which also applies for the measurement environment 20. That is, different nodes may be adapted for different purposes.

FIG. 5d shows a schematic block diagram of a node 50d according to an embodiment. The node 50d comprises an interface 72 configured for exchanging a wired signal, e.g., the signal 42 and/or 44. The wired signal 42 and/or 44 may relate to an electrical signal being transported or communicated by use of a wire, i.e., material being conductive. Alternatively, the signal 42 and/or 44 may be wired in a different sense, e.g., an optical signal being communicated by use of an optical fibre, wherein both concepts may be combined, e.g., one of signals 42 and 44 may be an electric signal whilst the other is an optical signal.

The node 50d comprises an antenna arrangement 74 comprising a plurality of antenna elements 74₁ to 74_{N}, i.e., antennas. For example, the antenna arrangement 74 may comprise 2, 4, 8 or 16 antennas, wherein the number is neither limited to the number of 16 nor to even numbers nor to powers of 2 and might also be, for example, 5, 7 or 25.

The node 50d is configured for at least one of an RX-beamforming and a TX-beamforming. For example, the node 50d is implemented so as to allow for RX-beamforming whilst not allowing for TX-beamforming. Alternatively, the node 50d may allow for TX-beamforming whilst not allowing for RX-beamforming. Alternatively and advantageously, the node 50d is adapted so as to allow for TX-beamforming and for RX-beamforming. For RX-beamforming, the node is configured for providing the wired signal 42 based on a wireless signal 76 received with the antenna arrangement 74 so as to receive the signal 76 by use of RX-beamforming. For TX-beamforming, the node 50d is configured for receiving the signal 44 and for transmitting a wireless signal 78 by use of TX-beamforming and by use of the antenna arrangement 74. The signal 42 may be received and the signal 42 may be provided at the interface 72 which may form a joint interface for both signals but may also allow to separate the signals physically, e.g., by implementing two distinct interfaces.

The node 50d comprises a transceiver 82 which may be implemented similar or equal to the transceiver 66. A control signal 84 may be used to control the transceiver 82 and an array unit 86 which is connected to the antenna elements 74₁ to 74_{N} of the antenna arrangement 74 and to the transceiver 82. That is, the transceiver 82 may provide a signal to the array unit 86 and/or receive signals from the array unit 86, wherein the array unit 86 allows to implement beamforming weights to the respective transmission or reception chains so as to implement the beamforming. For example, the array unit 86 may comprise a beamforming network or the like which is also controlled by the control signal 84.

Whiles the antenna elements 74₁ to 74_{N} are illustrated as being individual antennas, this does not exclude or prevent embodiments to have groups of antennas being connected commonly or jointly to the array unit, thereby forming a joint antenna.

The node 50d may be configured for executing a control command, for example, received with the control signal 84, to either use the antenna arrangement 74 in a reception mode, in a transmission mode or in a full-duplex mode.

The control signal 84 may be received with the node 50d by use of a control interface for receiving the control signal 84. For example, such a signal may be received from an external control unit, for example, a control unit of the measurement environment 20 or the like and may indicate instructions for controlling the node 50d in a reception mode for RX-beamforming and/or in a transmission mode for TX-beamforming. Alternatively, or in addition, the node 50d may comprise a control unit for controlling the node 50d in the reception mode for RX-beamforming and/or in a transition mode for TX-beamforming. That is, the control signal 84 may also be generated and/or provided internally.

When referring again to the array unit 86, same may be configured for controlling the antenna arrangement 74 so as to allow the node 50d to generate different beam patterns (RX and/or TX) with the array unit. In particular, the node may be configured for controlling the array unit 86 so as to variably generate different beam patterns.

The antenna elements 74₁ to 74_{N} may comprise similar antenna characteristics when receiving the wireless signal and/or when transmitting the wireless signal. As a similar antenna characteristic, one may understand that the antenna characteristic is equal within a tolerance range of, e.g., ±15%, ±10% or ±5%, wherein the characteristics may include, for example, a radiation pattern of the single antenna element, a polarity, a phase shift and/or a reciprocity.

According to an embodiment, the antenna elements 74₁ to 74_{N} may also deviate from a same or equal characteristic by a defined metric, i.e., by a design parameter beyond manufacturing tolerances. For example, where a node comprises a single antenna with a given gain, beamwidth and so on, a plurality of elements could be arranged/configured to form an array that has similar gain, beamwidth and so on. For example, such a metric may allow for adaptations to the measurement environment or the like.

Further, the node 50d may be configured for compensating deviations between the antenna elements 74₁ to 74_{N} within at least one characteristic with or without considering a defined metric relating to the deviations. That is, beyond a requirement of such a metric, compensation methods may be used, e.g., calibration, adaptation and/or correction. Similar considerations apply when combinations of antennas are used. For example, the node 50d may comprise a multiantenna arrangement, i.e., multiple antenna arrangements each adapted for RX purpose and/or TX purpose and each configured for an independent beamforming and/or a joint beamforming.

Embodiments relate to a measurement environment being adapted for implementing a method described herein. Further embodiments relate to a measurement environment having at least one or advantageously a plurality of nodes being adapted as described for the node 50d. Such a measurement environment may comprise the nodes to be arranged at least as a part of a Buckyball structure, e.g., the Buckyball structure 30, wherein a different number of nodes may be used.

The measurement environment may be configured for implementing a rotatory movement of the plurality of nodes and/or a translatory movement of the plurality of nodes with respect to the DUT.

The measurement environment may comprise a link antenna arrangement being implemented, as described, as a virtual antenna, a physical link antenna and/or a combination thereof. A link antenna arrangement to be formed as a virtual antenna arrangement may be implemented by at least one node of the measurement environment, i.e., the respective node may behave (receive and/or transmit signals) as the DUT would expect the link antenna to behave. Such a measurement environment may be configured for executing a method according to the description provided herein. According to an embodiment, a measurement environment has a plurality of nodes as described for the measurement environment 20. The measurement environment 20 may be implemented such that each node is adapted for transmission and/or reception purpose, e.g., one of the nodes 40a to 40d and/or 50a to 50d. That is, each node is configured for receiving a signal from the DUT and/or transmitting a signal to the DUT within a measurement procedure. The measurement environment is adapted to implement a virtual link antenna arrangement using the plurality of nodes which allows to freely adapt parameters of the link antenna within the measurement environment such as a position that may be simulated jointly or individually by a node or a plurality of nodes, a polarization, a line-of-sight (LoS) scenario, non-LoS scenarios, multipath-propagation scenarios or the like. Such a measurement environment may allow to implement same without a physical or dedicated link antenna being used to pair with the DUT which is tested by use of the nodes. However, this does not exclude to have a link antenna for other DUTs.

In other words, at the nodes, one or more antennas can be used for the purpose of transmission or reception or both. With respect to these nodes, the position and/or orientation of the antennas may be similar or dissimilar. Similarly, such antenna position and orientation variations between nodes may also exist. These antennas can be connected to a transmitter, a receiver, a transceiver or a combination thereof. Additionally, when there is a plurality of antennas at one or more nodes, these antennas can be arranged to form an antenna array for transmission and/or reception, as described, for example, in connection with FIG. 5d, the chosen example of a radio node configured for transmission and/or reception purposes and being equipped with a plurality of antennas that can be arranged to form an antenna array. In one embodiment, the node 50d is configured for either transmission or reception purposes. The characteristics of the mentioned antennas (e.g., antenna radiation pattern, orientation, phase centre and direction, polarization, orbital angular momentum, etc.) when used for transmission and/or reception, could be similar. Ideally, transmission and reception properties may be identical, at least within a tolerance range, including pattern reciprocity. A departure from the ideal condition may be tolerated according to a defined metric. In association with each node, a circuit capable of transmission, reception or both may be used. This circuit can be located at the node (in a distributed sense) or away from the node (in a centralized sense) in a measurement environment. Combinations of a distributed and a centralized arrangement are subject of embodiments. The Buckyball structure, i.e., the node arrangement, may be mechanically rotated and/or translated in one or more directions with respect to its centre, in order to, e.g., improve spatial sampling, determine compensation parameters, identify/estimate/localize/compute radiation reference points of the DUT.

In the following, further details will be provided for a method for determining a beam correspondence parameter according to an embodiment which may also be implemented by a measurement environment according to an embodiment.

When referring again to FIG. 1, the method may be executed so as to comprise using a link antenna arrangement of the measurement environment which may be realized, as described, as a physical link antenna, a virtual link antenna or a combination thereof. For example, a pairing with the DUT may be obtained by use of the link antenna arrangement. Alternatively, or in addition, the link antenna arrangement may be used for transmitting and/or receiving different signals. The link antenna arrangement may comprise a similar antenna characteristic when receiving a wireless signal and when transmitting a wireless signal. Alternatively, or in addition, the virtual link antenna may comprise a similar characteristic in view of transmission and/or reception when compared to a physical link antenna which may be defined, e.g., by test method requirements or the like. A similar characteristic of the link antenna arrangement may be understood as being equal within a tolerance range of, e.g., ±15%, ±10% or ±5% of a characteristic that includes reciprocity, a radiation pattern/characteristic, a reception pattern/characteristic and/or a polarization.

However, the link antenna arrangement, although having a similar antenna characteristic, may deviate from the same characteristic by a defined metric so as to comprise the similar characteristic. That is, the link antenna arrangement may vary within the single antenna elements as described for the node 50d.

The antenna characteristic of the virtual link antenna may deviate from the substituted physical link antenna by a defined metric. Characteristics of the non-virtual, i.e., physical, link antenna and of the virtual link antenna can be compared in order assess the similarity of the two. Examples of such characteristics include gain, beam width, first side lobe level, cross-polar ratio, etc. A measure of the difference or deviation from one to the other may be considered as a respective metric. In other words, embodiments relate to replacing a dedicated, separate, physical or independent link antenna with a virtual link antenna, i.e., one that is constructed using the available nodes of the measurement environment.

Compensation of deviations within at least one characteristic of the antenna characteristic, i.e., deviations between the physical link antenna and the virtual link antenna, may be compensated for with or without considering a defined metric relating to the deviations. For example, if there is a gain difference between the non-virtual and the virtual link antenna, such a gain difference may be known and may be compensated.

After having provided several details in connection with the measurement environment, further details are now provided in connection with embodied methods. As described, the DUT is caused to generate a second beam so as to form a beam pair with the first beam of the measurement environment which is a TX beam or an RX beam in method 100.

The beam pair may provide for a unidirectional link, e.g., an uplink connection or a downlink connection with the measurement environment but may also form at least a part of a bidirectional link. For example, the DUT may be caused to generate at least one additional beam of at least one additional beam pair, allowing to have at least two uplink-connections and/or at least two downlink connections but, in particular, also combinations thereof, therefore allowing for bi-directional communication. A number of beam pairs to be maintained by the DUT is, however, not limited to a number of 2 and may be, for example, 3, 4, 5 or more.

Determining the beam correspondence parameter may comprise a use of an internal parameter of the DUT. The internal parameter may be any value from inside the DUT which allows an assessment of the performance of the receiver link, e.g., if the DUT has multiple antenna ports then the feedback relating to the beam correspondence parameter may comprise an MRC (maximum ratio combining) or other digital signal processing applied in the DUT which may be, for example, implementation specific.

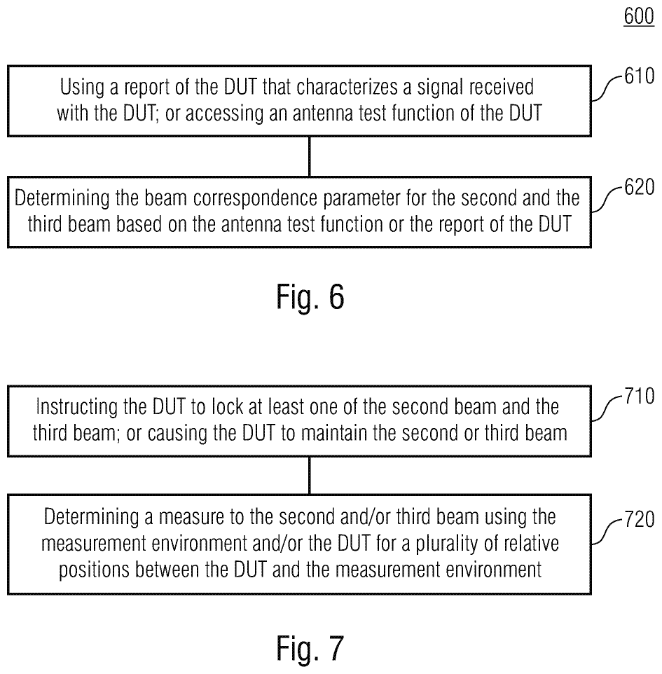

FIG. 6 shows a schematic flow of a method 600 which may be executed for using the internal parameter of the DUT and, thus, as at least a part of determining the beam correspondence parameter, e.g., as part of the step 140. A step 610 comprises assessing an antenna test function of the DUT, e.g., using the measurement environment or using a report of the DUT that may indicate an amplitude of a received signal of the DUT. A step 620 comprises determining the beam correspondence parameter for the second beam and the third beam pair based on the antenna test function. As mentioned, any value from inside the UE may be used as the antenna test function that allows to assess the performance of the receiver link. That is, a measure may be determined that allows to quantify or qualify how well the beam selected by the DUT fits to the beam of the measurement environment.

For example, the measurement environment and/or the DUT may measure a phase (e.g., in addition to amplitude). For example, the measurement environment may be adapted to create signals/beams whose amplitude and phase can be controlled in view of controlling the illumination of the beam and that it may measure the amplitude and phase of signals/beams in view of observations made by receiving signals.

FIG. 7 shows a schematic flow chart of a method 700 according to an embodiment that may be executed additionally or as an alternative to method 600 and may be executed optionally for determining the beam correspondence parameter, e.g., to further define step 140. A step 710 comprises instructing the DUT to lock at least one of the second beam and the third beam, e.g., the RX beam and/or the TX beam or causing the DUT to maintain the respective beam. Locking or maintaining the beam may relate to keep at least one characteristic of the beam constant, e.g., a relative direction/spatial property of one or more lobes, a polarization, a phase, a frequency, a used code, symbols or the like. Maintaining the beam may thus include an adaptive beam with some fixed property e.g., gains, powers, shapes, polarization, phases, codes or the like of one or more of a main lobe, a side lobe and/or a null towards the one and/or the other link antenna. That is, embodiments relate to lock/maintain the whole beam (Rx and/or TX) or to lock/maintain properties such as the direction/spatial property of the main lobe, side lobes or nulls. This may also allow to assess/evaluate dynamic performance like “tracking” a link to a base station or measurement environment while the UE is dynamically changed in its relative position to the measurement environment or link antenna or base station.

For example, when instructing the DUT to lock the second beam, the nodes of the measurement environment may be moved with respect to the DUT therefore allowing for different relative positions between the nodes and the beam so as to provide for a high spatial resolution of the measurement. A similar result may be obtained when causing the

DUT to maintain the second beam, i.e., to keep transmission and/or reception directions of one or more lobes and/or nulls constant. A step 720 comprises determining a measure related to the second beam and /or the third beam using the measurement environment and/or the DUT for a plurality of relative positions between the DUT and the measurement environment, e.g., by rotating the DUT with respect to the nodes and/or the nodes with respect to the DUT.

That is, a beam pair comprises a TX beam and an RX beam and is generated jointly with the measurement environment and the DUT, whilst the DUT generates two beams whose correspondence is to be evaluated. That is, although the DUT generates a set of beams forming a part of the the beam pair, this generation is based on cooperation/interaction/as a response with the measurement environment which provides for the related TX beam and/or RX beam. Determining the beam correspondence parameter may comprise comparing a metric related to the second beam and a metric related to the third beam, e.g., transmitted power and receive power or any other suitable measures. Determining such a metric or measure may allow beam correspondence assessments to be made with or without accessing the antenna test function (ATF) and/or a beam lock instruction. For example, the measurement environment can identify beams using electronic signals, e.g., by use of electronic marker.

The optional pairing may be executed by use of a link antenna that may be virtual or non-virtual, e.g., physical or a combination thereof, i.e., a physical link antenna being combined with one or more nodes of a measurement environment. The optional pairing may comprise a use of electronic markers within an exchange of a signal. For example, the electronic marker may comprise at least one of a synchronization block signal (SSB), a channel state information reference signal (CSI-RS) and/or a sounding reference signal (SRS).

In the given example, the DUT may be caused to generate the TX beam based on an RX beam that is formed responsive to a TX beam of the measurement environment. Alternatively, the DUT may generate a TX beam towards the measurement environment and wait for a response to generate an RX beam pattern. For both cases, the metric related to the TX beam of the DUT may be measured at a physical or virtual link antenna of the measurement environment, e.g., to determine results relating to the TX beam of the beam pair. Alternatively, or in addition, the DUT may generate an RX beam and the metric may be measured at the DUT, e.g., at an antenna test function of the DUT, i.e., by using any suitable measure inside the DUT. For example, an orchestrated measurement may be executed by use of the measurement environment into two directions, keeping the RX and TX beams locked at the DUT and comparing the measurements in a way that the pattern or link performance is assessed, e.g., in a spherical meaning.

It is to be noted that beam correspondence assessments, i.e., measurements, may be made with or without assessing the specific antenna test function and/or using a beam locking instruction. As described, the beam locking instruction may cause locking the entire beam pattern or parts thereof, e.g., spatial properties of it, e.g. a Null, main lobe, side lobe or the like. For example, the measurement environment may be configured for identifying the beams using electronic signals/markers and such information may form a basis for an orchestrated measurement in two directions as beams that are generated may be separated during reception.

The metric may be related to a spatial characteristic of the beam, i.e., it may be evaluated whether the beam selected by the DUT is an optimal or suited beam and points towards the correct adaption.

Alternatively, or in addition, the metric may be related to at least one of a measure per direction and/or to a measure accumulated over a plurality or all directions such as a cumulative distribution function (CDF). Alternatively, or in addition, the metric may be related to a measure per frequency and/or a measure accumulated over a predefined bandwidth such as one or more carriers, sub-carriers or the like. Alternatively, or in addition, the metric may be related to a measure per polarization and/or a measure accumulated over orthogonal polarizations.

Alternatively, or in addition, the metric may be related to a changing and/or a constant characteristic of one or more beams, e.g., a spatial property of the second and/or third beam; a gain value of at least a part of the beam pattern; a power value of at least a part of the beam pattern; a polarization of at least a part of the beam pattern; a phase including a phase shift of at least a part of the beam pattern; a shape of at least a part of the beam pattern; and/or a code used in at least a part of the beam pattern.

When performing a method according to an embodiment, the DUT may be caused, during an instance of testing, to simultaneously maintain a beam of a first beam pair and a beam of a second beam pair. That is, such a simultaneous maintenance may relate to a same instance of time, e.g., when using a frequency division duplex (FDD) or code division duplex

(CDM) scheme or the like but may also relate to different slots of a time frame thus to different but related instances of time, e.g., in a time division duplex (TDD) scheme. For example, but not necessarily, the first beam pair and the second beam pair are generated responsive to a use of different link antenna arrangements of a measurement environment, i.e., that the DUT communicates into different directions or towards different targets which is advantageously possible by using virtual link antennas as described in accordance with embodiments. Such a configuration may allow to simulate, for example, a multi base station scenario in which a UE is linked with or aware of two or more base station and is adapted so as to form at least a part of a beam pair towards (LoS/nLoS) two base stations and/or to avoid interference at a location of at least one of those targets or the like. For example, two link antennas may be arranged or implemented in the measurement environment allowing for such tests. Alternatively, or in addition, the DUT may maintain another beam pair towards a same target, e.g., in a single base station scenario. The first beam pair and the second beam pair first beam pair may both be part of a respective uplink connection, may form a part of a respective downlink connection or, alternatively, one of them may form a part of an uplink connection and the other may form a part of a downlink connection.

Determining the beam correspondence parameter may comprise activating a measurement procedure. Transmit signals may be fed from different directions of the measurement environment to the DUT so as to allow to determine a receive antenna beam pattern. The transmit signals may be fed consecutively or simultaneously. A report may be received from the DUT. The report may contain information related to a direct or indirect reporting and may be associated with the transmitted signals. The DUT may report about beams generated by the DUT, e.g., by reporting parameters such as a beam label, a beam ID or the like and/or may report about results of measurements it has performed, i.e., about what it receives. For example, the report may relate to parameters determined at an antenna test function, i.e., may relate to antenna test function signals of the DUT. The report may contain information relating to one or more of an amplitude, a gain value, a polarization, a phase or the like, wherein a plurality of such values may allow to obtain spatial information, e.g., 2D information or 3D information. That is, signals may be transmitted to the DUT by use of the measurement environment and parameters indicating a reception power or reception quality may be received from the DUT.

Methods according to an embodiment may comprise measuring a transmit beam pattern of the DUT, i.e., a pattern of a beam being transmitted by the DUT, the beam pattern corresponding to a pairing signal of the measurement environment and, thus, a beam which is selected responsive to a signal received with the DUT. The transmit beam pattern of the DUT may be measured with the plurality of probes of the measurement environment consecutively or simultaneously based on reference signals embedded in a signal transmitted from the DUT, while providing for a signal for pairing with a link antenna arrangement. Alternatively, or in addition, the DUT may be instructed for locking the beam so as to allow for measurements thereafter. The pairing signal may describe a pilot signal known to the DUT and may allow the DUT to optimize its beam former for reception. For example, a beacon or the like may be used for such purpose.

Determining the beam correspondence parameter may comprise measuring, at an antenna test function port of the DUT and/or least one node of the measurement environment at least one of a power per port/node, an interference level, a noise level, unwanted intermodulation components, a phase (narrowband on reference signal) and a power delay profile. Each of these parameters and combinations thereof may allow for evaluating the correspondence between a TX beam and an RX beam. The measurement may be based on known reference signals or signatures and may be done crosswise. Furthermore, for example, interference or noise levels may be measured using blind signal extraction methods separating noise from deterministic signals that have unknown identifiers or markers.

A method according to an embodiment comprises arranging at least one measurement node of the measurement environment in a known geometry, calibrating an exposure to signals for the DUT to obtain a calibrated exposure, i.e., to obtain a known exposure for the DUT. The method comprises determining the beam correspondence parameter based on comparing the calibrated exposure with a signal transmitted from the DUT and received with the measurement environment as a response signal sent to the DUT. This allows for a measurement from outside the DUT with particular properties such as polarization, phase fluctuations, frequency selectivity and the like.

Embodiments relate to an orchestrated measurement into both directions, TX and RX and correlating the results. For example, by shifting a relative position between the DUT and the nodes by having fixed beams, e.g., using step 710, an increase or a decrease of a power level may be determined with the measurement environment as well as other parameters such as a phase shift. Thereby, a pattern similarity test may be approached in view of a receive beam pattern and a transmit beam pattern.

In other words, a link antenna being used for the pairing or the like may be an antenna used to form a communication pairing between the test equipment/measurement environment and the DUT. The link antenna (LA) can be:
Separate from the nodes/Buckyball structure, i.e., an additional antenna;
A virtual antenna which is part of the Buckyball, e.g., one of the 60 nodes or a combination of nodes (thereby controlling the beamwidth and/or the directional illumination of the DUT); and/or
A combination of the above (separate LA and antennas of Buckyball).

A link antenna with respect to the measurement procedure may be one of the above-mentioned options that can be used for transmission and/or reception. The characteristics of the link antenna (e.g., antenna radiation pattern, direction, polarization, orbital angular momentum, etc.) when used for transmission and/or reception may be similar and the link antenna may be able to stimulate and receive/measure radio waves in, for example, all possible polarizations, linearly/circularly polarized). Ideally, transmission and reception properties may be identical. A departure from the ideal condition may be tolerated according to a defined metric. Beyond a requirement of this metric, compensation methods may be used, e.g., calibration, adaptation, correction or the like. The link antenna can be identified by a unique/identifiable/numbered (logical) antenna port. The signals conveyed by the link antenna can be identified using electronic markers, e.g., SSB, CSI-RS, SRS, etc., embedded in the transmitted signals from the measurement equipment/measurement environment and/or the DUT. Enhanced measurements and tests of the DUT may be facilitated through access to its antenna test function (ATF) and the associated logical ports defined therein.

The beam correspondence parameters may be obtained/measured with a single link antenna for transmission and reception that may also be determined with a multi-probe test and measurement environment for transmission and reception.

A procedure to obtain/measure beam correspondence with one link antenna for transmission and reception may comprise as solution #1:
1. User equipment (UE)/DuT on turntable is set to position P_0 of P_K (link antenna is in far field (FF) and UE experiences a signal e.g., a plane wave from one or more direction(s)
2. Bi-directional link between link antenna and UE is established (RACCH accessed by UE and in two or more steps UE is set in RRC connected state)
3. ME triggers/initiates/configures test mode (measurement mode) in order to indicate/configure UE/DUT into certain procedures for testing
4. ME sends “Lock beam” command with respect to Tx and Rx beams simultaneously or consecutively
5. DUT and/or ME measure power and/or phase on reference signal (RS) or other suitable signals and store/exchange for every measured position/direction e.g., (theta/phi), (azimuth/elevation) and/or (solid angle/steradian)
   i. Measure at LA for “locked” Tx beam of UE (e.g., beam 29₃, and/or with time stamp or configuration/parameter set (angles))
   ii. Measure at ATF for “locked” RX beam of UE (e.g., beam 29₂, and/or with time stamp or configuration/parameter set (angles))

Suitable metrics to compare TX and RX beams in terms of beam correspondence may be per direction (theta/phi), (azimuth/elevation) and/or (solid angle/steradian) may be accumulated over multiple or all directions (e.g., CDF).

When using a multiprobe test and measurement environment for transmission and reception, the measurement environment 20 may be used. Therein, the Buckyball of FIG. 3 was described as one option and offers an equal distribution with respect to distance/vertices between adjacent probes/nodes. The UE/DUT experiences radio signals in an effective far field and/or equivalent near field corresponding to an adjustable or selectable direction of arrival (DoA) spectrum corresponding to multipath components (MPC) of the wireless propagation in a typical environment. Such a DoA spectrum can be formed in transit mode from the measurement environment to the DUT and measured from the DUT at the measurement environment exploiting the capability of simultaneously or consecutively transmitting or receiving from the different nodes/probes while the UE/DUT is in RRC connected mode and “beam locked”. The procedure may comprise:
1. Follow beam correspondence measurement procedure 1 . . . 5 (see Solution #1) using beam lock command
   a. The particular difference to solution #1 is that the Link Antenna can be a variant of the described implementations, i.e., separate from the nodes/Buckyball structure, i.e., an additional antenna; a virtual antenna which is part of the Buckyball; and/or a combination of the above (separate LA and antennas of Buckyball), exposing the UE/DuT a variable or configurable DoA spectrum when establishing the link before sending “beam lock” command to UE/DuT.
   b. When beam is “locked” then the ME activates a measurement procedure allowing the system/method to determine the receive antenna beam pattern by feeding transmit signals from different directions/nodes of the ME consecutively or simultaneously while the UE/DuT is reporting the associated ATF signals.
   c. The corresponding transmit beam pattern of the UE/DuT can be measured by the distributed nodes/sensors of the ME consecutively or simultaneously based on RS embedded in the transmit signal from the DuT, while the Tx beam from the UE/DuT is “locked”.
   d. The above two steps can be combined with a rotation of the UE while the transmit/receive beam(s) is/(are) locked.
2. Follow 1 . . . 5 (see Solution #1) without beam lock
   a. The particular difference to the previous solution#2 WITH beam lock is the fact that the UE/DuT is receiving a particular DoA spectrum of the multiprobe link antenna with a selected receive beam, reporting the values from the ATF and responding with a corresponding transmit beam towards the ME.
   b. The ME can operate its receiver(s) in inverse beam correspondence mode (the receive beam pattern corresponds to a calibrated transmit beam pattern of the link antenna)
   c. The ME can measure the transmit beam pattern of the UE/DuT by evaluating the sensor input from all or a few of the distributed receive antennas.
   d. A variant of the above configuration includes that the LA of the ME is using a particular DoA spectrum, while the opposite link direction is measured with an aperture allowing to sample a DoA spectrum at the ME larger, equal or smaller than offered to the UE/DuT.

Both variants described above include options to probe/sense all practically relevant variants of, e.g., direction, polarizations, DOA spectra, etc., in order to test the DUT under conditions which are close to a real-world scenario at least as far as possible. Measurements at the ATF port(s) and multiprobe system may include a power per port/probe and/or a phase (narrowband or reference signal) and/or a power delay profile (representing a power versus direction representation of the TX (RX beam) and TX delays applied into these distances.

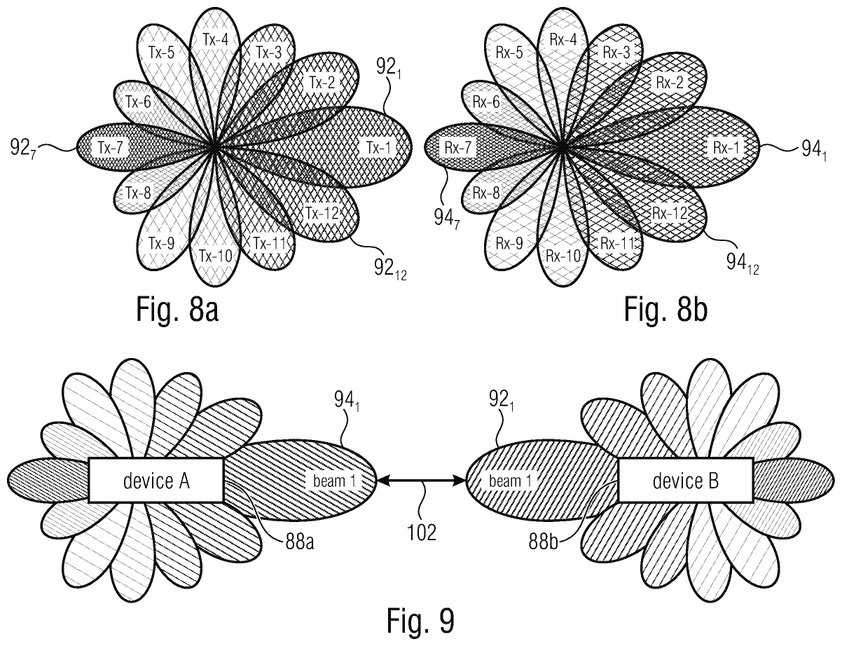

FIGS. 8a and 8b show an example of simplified beam patterns producible by a multibeam antenna arrangement created by a communication device, e.g., a DUT in connection with embodiments described herein. For simplicity, the transmission beam patterns 92ᵢ and reception beam patterns 94ⱼ shown in FIGS. 8a (transmission beam patterns) and FIG. 8b (reception beam patterns) are illustrated to be identical, whereas in a practical system differences between the two sets of patterns may exist to some greater or lesser extent. The figures introduce the concept that beam pairing can be applied to a single device, whereby the following set of 12 beam pairs may be identified: TX-1/RX-1; TX-2/RX-2; TX3/RX-3; TX-4/RX-4; TX-5/RX-5; TX-6/RX-6; TX-7/RX-7; TX-8/RX-8; TX-9/RX-9; TX-10/RX-10; TX-11/RX-11; and TX-12/RX-12. For example, when receiving a signal by use of a reception beam 94 of an above identified beam pair, the DUT may be caused to transmit a signal by use of a corresponding TX-beam 92. In other words, FIGS. 8a and 8b show an example of the transmission and reception beam patterns of the same device comprising 12 discernible/distinguishable beams, wherein each beam is the main lobe of a particular antenna radiation pattern. For convenience, the side lobes of all patterns have been omitted.

In the following, examples of a beam pair combination between two devices is illustrated. In FIGS. 9 and 10, a single beam pair is illustrated. In FIG. 9, an example of beam pairing between two devices in which beam 1 of device 88a (Device A) forms a line-of-sight (LoS) alignment or path 102 with beam 1 of device 88b (Device B) is shown. The beams of both devices can be used for either transmission or reception purposes.

FIG. 10 shows an example of beam pairing between devices 88a and 88c. Due to a presence of a blocking object 96, beam 92₁ and 94₁ do not form an LoS-path but beams 92₁ and 94₂ form as non-LoS path 104 by use of a reflective object 98 and, thus, a non-line-of-sight pair-(nLoS).

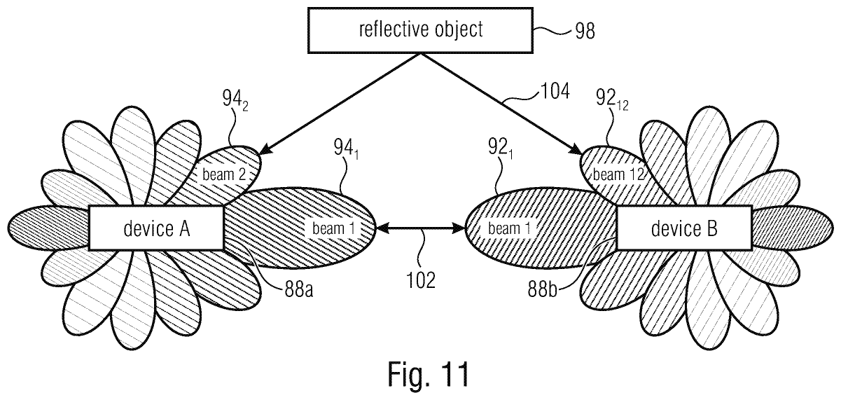

FIG. 11 shows a schematic view on devices 88a and 88b of FIG. 9 using an additional non-line-of-sight path based on reflections on reflective object 98. In the illustrated example, two beam pairs between devices 88a and 88b are thus used. Beam 1 (94₁) of device 88a forms a line-of-sight pairing with beam 92₁ of device 88b and, due to a reflection, beam 94₂ of device 88a and beam 92₁₂ of device 88b form a non-line-of-sight pairing.

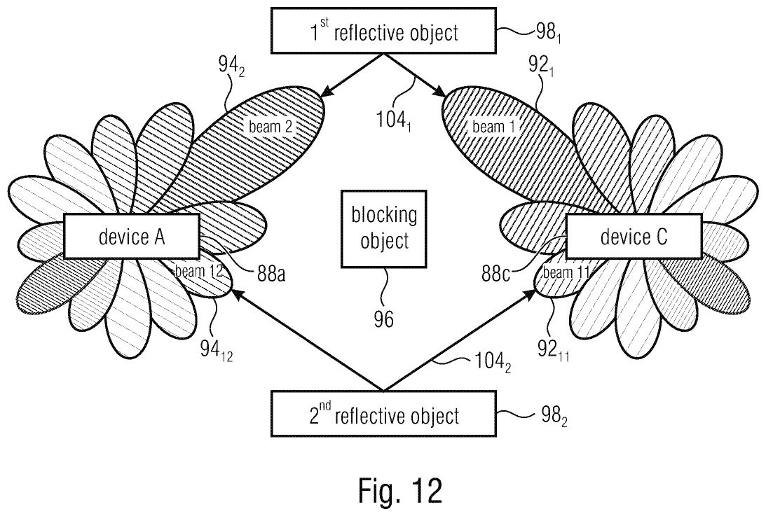

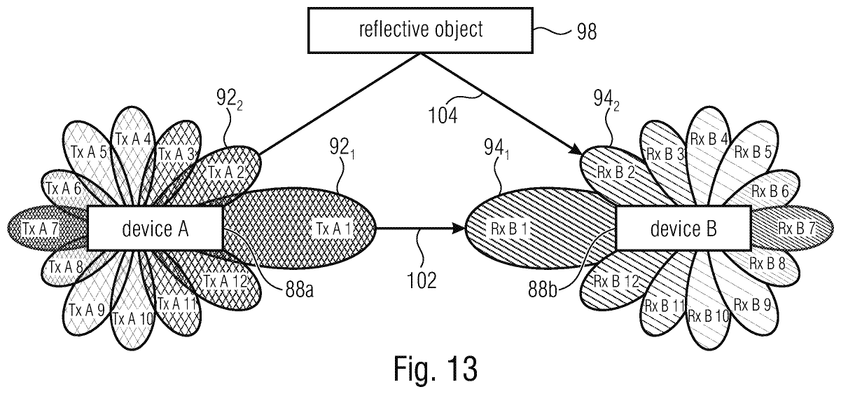

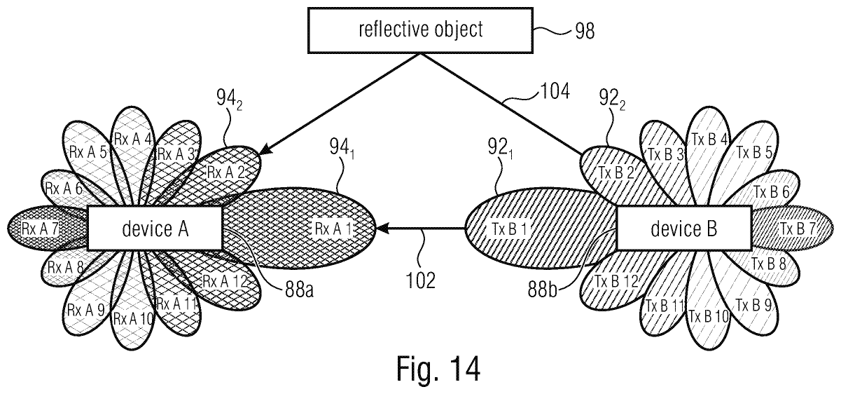

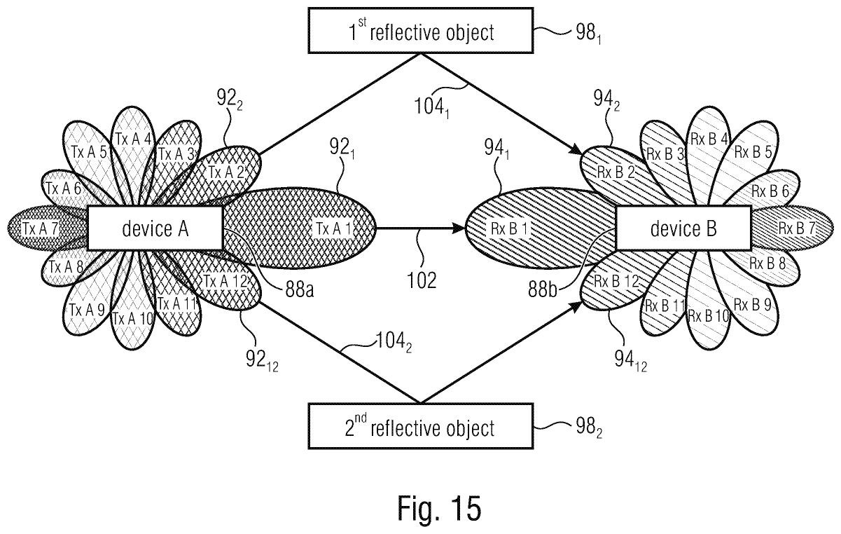

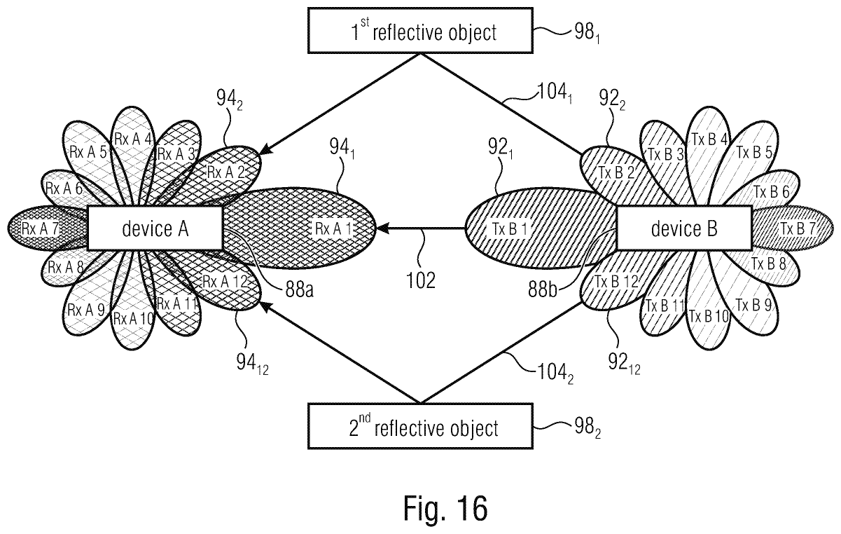

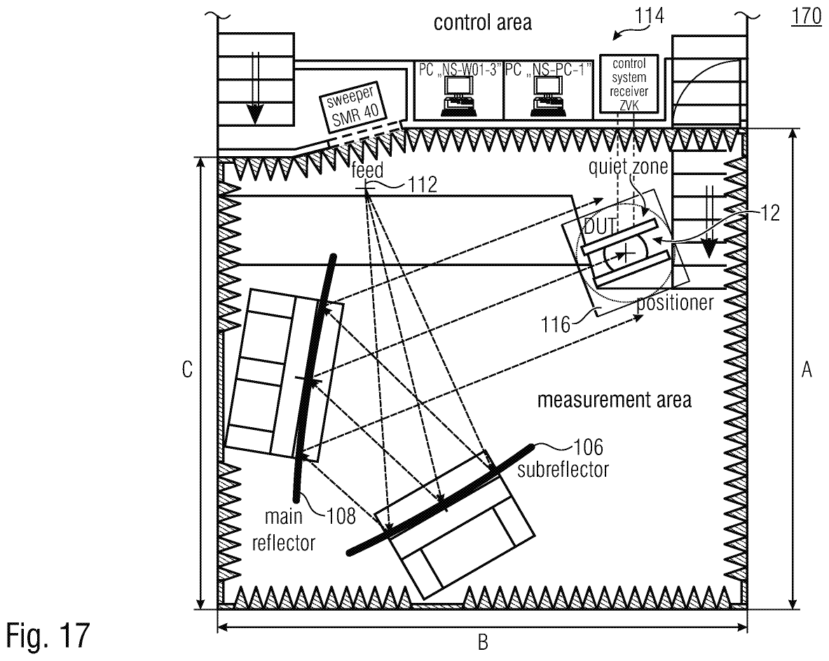

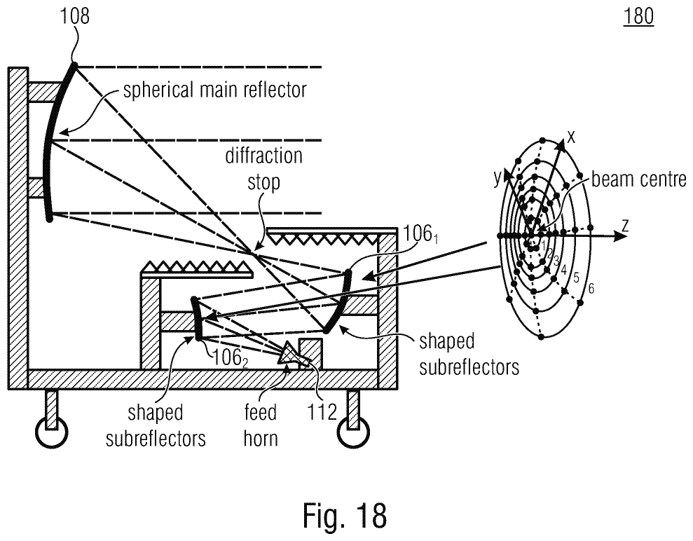

FIG. 12 shows a schematic diagram illustrating an example expanding the scenario of FIG. 10 in which a second reflective object 98₂ allows for a second non-line-of-sight path/pairing using beams 92₁₁ of device 88c and beam 94₁₂ of device 88a. That is, an example of two beam pairs between devices 88a and 88c are shown. Due to the presence of a combination of blocking and reflective objects, beam 94₂ of device 88a and beam 92₁ of device 88c form a non-line-of-sight pairing. Similarly, beam 94₁₂ of device 88a and beam 92₁₁ of device 88c also form a non-line-of-sight pairing.

FIG. 13 shows an example scenario of two devices 88a and 88b providing for two TX-RX beam pairs between devices 88a and 88b. Beam TX A 1 (92₁) of device 88a forms a line-of-sight pairing with beam RX B 1 (94₁) of device 88b and, due to a reflection, beam TX A 2 (92₂) of device 88a and beam RX B 2 (94₂) of device 88bv form a non-line-of-sight pairing.

FIG. 14 shows an example scenario of two TX-RX beam pairs between devices 88a and 88b. Beam TX B 1 (92₁) of device 88b forms a line-of-sight pairing with device beam RX A 1 (94₁) of device 88a and, due to a reflection, beam TX B 2 (92₂) of device 88b and beam RX A 2 (94₂) of device 88a form a non-line-of-sight pairing.

FIG. 15 shows an example scenario of three TX-RX beam pairs between devices 88a and 88b. Beam TX A 1 (92₁) of device 88a forms a line-of-sight pairing with beam RX B 1 (94₁) of device 88b. Due to reflections, beam TX A 2 (92₂) of device 88a and beam RX B 2 (94₂) of device 88b and, similarly, beam TX A 12 (92₁₂) of device 88a and beam RX B 12 (94₁₂) of device 88b form a non-line-of-sight pairing.

FIG. 16 shows an example scenario in which transmission and reception is inverted when compared to FIG. 15 such that three TX-RX beam pairs between devices 88b and 88a exist. Beam TX B 1 (92₁) of device 88b forms a line-of-sight pairing with beam RX A 1 (94₁) of device 88a. Due to reflections, beams TX B 2 (92₂) of device 88b and beam RX A 2 (94₂) of device 88a and, similarly, beam TX B 12 (92₁₂) of device 88b and beam RX A 12 (94₁₂) of device 88a form non-line-of-sight pairings.

With reference to FIGS. 10, 11, 12, 13, 14, 15 and 16 in which reflective objects are shown, it is to be noted that one aspect of embodiments described herein is to arrange the measurement environment in such a way that only one or more reflectors form part of the apparatus together with either single or multiple probes or nodes.

That is, devices 88a, 88b and 88c may be implemented by the measurement environment and/or as a DUT.

FIG. 17 shows a schematic top view of a contact antenna test range (CATR) 170 according to an embodiment. The CATR comprises a sub-reflector 106 and a main reflector 108 for reflecting a signal of a feed antenna 112 towards the DUT 12. Measurement probes are not shown in FIG. 17. Measurement equipment 114 may be connected to the feed antenna 112 and to the measurement probes. A position 116 may be used for changing a relative position of the DUT within a measurement chamber or measurement area.

Example dimensions A B and C of such a chamber are, by example only, 6.3 meters (A), 7.05 meters (B) and 5.92 meters (C).

In other words, FIG. 17 shows a compact antenna test range comprised of a single feed, a sub-reflector and a main-reflector.

In contrast, FIG. 18 shows a mobile CATR 180 having two sub-reflectors 106₁ and 106₂ and one main reflector 108 to reflect a wave generated by a feed horn 112. Sub-reflectors 106₁, 106₂ and main reflector 108 may be shaped and/or spherical. The CATRs 170 and 180 may be combined with a multi-probe or multi-node measurement environment, i.e., one or more nodes according to embodiments may be arranged so as to measure waves generated with the DUT and possibly of the feed horn 112. According to an embodiment, the measurement environment 170 is equipped with one or more nodes described herein, e.g., nodes 50d and/or is implemented to comprise at least of a Buckyball structure as described in connection with FIG. 3, e.g., to evaluate the DUT. A measurement environment according to an embodiment may thus comprise at least one reflector between a link antenna arrangement and the DUT.

Further embodiments, however, also relate to implementing the feed horn 112 as a virtual link antenna by use of multiple or at least one node of the measurement environment.

In other words, it is identified that the flexibility offered by the apparatus disclosed herein allows a measurement environment to be built for the purpose of what shall be described as “virtual and simultaneous illumination and observation”. In other words, the arrangement of measurement probes and nodes can be done in such a way so as to enable the creation of one or more bi-centric links between the DUT and the measurement environment for the purpose of transmission and reception measurements, tests and assessments. These can either be formed separately, sequentially or jointly.

In other words, FIG. 18 shows a compact antenna test range in which a wheeled unit is equipped with two sub-reflectors and a main reflector. According to an embodiment, the measurement environment 180 is equipped with one or more nodes described herein, e.g., nodes 50d and/or is implemented to comprise at least of a Buckyball structure as described in connection with FIG. 3, e.g., to evaluate the DUT.

Embodiments thus relate to a combination of a CATR according to FIG. 17 and/or FIG. 18 with a multi-probe or multi-node measurement environment, in particular in connection with the virtual link antennas described.

Embodiments make use of inherent device functionality, currently unused for the purposes according to the described embodiments. By using the information supplied by multiple devices, improvements to the performance and use experience are obtained.

In other words, FIGS. 11 to 14 show examples of double beam pairs, while FIGS. 15 and 16 show triple beam pair examples. The concept of multiple beam pairing between devices and its logical extension, the notion of an arbitrary number of beam pairs being created between multiple devices is also covered by embodiments, i.e., a number of 1, 2, 3 or more, e.g., 4, 5 or 6 paths including LoS and/or nLoS components may be used. Whilst in FIGS. 9 to 12, the beams of each can be used for either the purposes of transmission or reception so as to facilitate a wireless connection between the two devices in either direction, according to an embodiment, beams may be used for the purpose of transmission and reception.

Embodiments described herein relate to determining a beam correspondence parameter. The inventors have further found a way to precisely determine a phase centre of a DUT, in particular of an antenna arrangement thereof.

Such a method comprises causing the DUT to generate a beam with the antenna arrangement. Such a step can be implemented as was described in connection with method 100 so as to cause the DUT to generate a TX beam or an RX beam. The method further comprises causing the DUT to lock or maintain at least a part of the beam, i.e., at least one characteristic of the beam. Such a step may be implemented in accordance with the locking or maintaining described in connection with determining the beam correspondence parameter.

The method further comprises measuring the beam for a plurality of relative directions with respect to the DUT to obtain measurement results. The higher the number of measurements, the higher the spatial resolution may be. As was discussed in connection with other embodiments, this may include measuring at least one or a variety of parameters. Such parameters may be measured at the measurement environment for a TX beam of the DUT and/or at the DUT and then reported, e.g., when the DUT forms an RX beam. The different positions may be based on moving the nodes and/or the DUT.

The method further comprises evaluating the measurement results to determine the phase centre. As the measurement environment may allow for different relative positions between the DUT and the measurement environment, based on the measurement results, a precise result of the phase centre may be obtained for the RX beam and/or TX beam.

According to an embodiment, the phase centre is determined for a plurality of beams generated and locked or maintained with the DUT. The different beams may be triggered, for example, using the virtual link antenna arrangement. The plurality of beams may comprise TX beams only, RX beams only or a combination. Evaluating a plurality of beams may allow to obtain further results on the DUT and/or to distances between different phase centres, e.g., of a same or of different antenna arrays.

In other words, the measurement environment can be arranged in such a manner that the phase centre of a DUT can be determined. Furthermore, through the use of a virtual link antenna, the phase centre of the DUT can be determined for different scan angles and can be measured at required frequencies. Increased accuracy and resolution of such phase centres can be further achieved by rotational and/or translational movement of the measurement environment.

As a phase centre one may understand, in accordance with the definition provided in “IEEE Std 145-2013: IEEE Standard for Definitions of Terms for Antennas” a location of a point associated with an antenna such that if it is taken as the center of a sphere the radius of which extends into the far field, the phase of a given field component over the surface of the radiation sphere is essentially constant, at least over that portion of the surface where the radiation is significant.

Such measurements may be performed together but also independently from determining the beam correspondence parameter.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Depending on certain implementation requirements, embodiments of the invention can be implemented in hardware or in software. The implementation can be performed using a digital storage medium, for example a floppy disk, a DVD, a CD, a ROM, a PROM, an EPROM, an EEPROM or a FLASH memory, having electronically readable control signals stored thereon, which cooperate (or are capable of cooperating) with a programmable computer system such that the respective method is performed.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine-readable carrier.

Other embodiments comprise the computer program for performing one of the methods described herein, stored on a machine-readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### REFERENCES

1. US 2019/0187199 A1, Heinz Mellein, “Test System and Method for Over the Air (OTA) Measurements Based on Randomly Adjusted Measurement Points”, Rohde&Schwarz, 20 Jun. 2019.
2. R4-1700888, “On EIRP/EIS spherical coverage requirement using CDF”, Sumitomo Electric, 3GPP TSG-RAN WG4 #82, 13-17 Feb. 2017, Athens, Greece.
3. R4-1709769, “On Measurement Grids for mm-wave NR”, Rohde&Schwarz, 3GPP TSG RAN WG4 NR#3, 18-21 Sep. 2017, Nagoya, Japan.
4. R4-1709832, “Measurements in Non-Anechoic Environments”, Fraunhofer HHI, Fraunhofer IIS, 3GPP TSG-RAN WG4 #82, 13-17 Feb. 2017, Athens, Greece.
5. R4-1809666, “On the combination of (electronic) beam sweeping and mechanical positioning techniques in OTA measurements”, Fraunhofer HHI, Fraunhofer IIS, Spirent, Ericsson, 3GPP TSG-RAN WG4 Meeting #88, 20-24 Aug. 2018, Gothenburg, Sweden.
6. https://www.compactrange.de/index.php/testi-facility/detailed-description
7. Chen, Xiaodong, Xiaoming Liu, Yu Jun-sheng, Yuan Yao, Chen Yang, Hai Feng Wang, Hairui Liu, Zejian Lu and Richard J. Wylde. “A tri-reflector compact antenna test range operating in the THz range.” 2015 9th European Conference on Antennas and Propagation (EuCAP) (2015): 1-3.

1. A computer-implemented method for determining a beam correspondence parameter of a device under test (DUT), the method comprising:
arranging the DUT within a measurement environment to allow an exchange of a wireless signal with the DUT;
generating a first beam with the measurement environment for the exchange of the wireless signal;
causing the DUT to generate, by using an antenna arrangement of the DUT, a second beam, to form a beam pair with the first beam, the beam pair comprising a TX beam and an RX beam and to generate a third beam corresponding to the second beam;
determining the beam correspondence parameter for the second beam and the third beam using a measurement characterizing the second beam and a measurement characterizing the third beam.

2. The computer implemented method of claim 1, wherein a link antenna arrangement of the measurement environment is implemented by a virtual link antenna that comprises, when compared to a physical link antenna, a similar antenna characteristic when receiving a wireless signal and when transmitting a wireless signal.

3. The computer implemented method of claim 2, wherein the antenna characteristic deviates from a same characteristic by a defined metric so as to comprise the similar characteristic.

4. The computer implemented method of claim 2, wherein the link antenna arrangement is a virtual link antenna that simulates a physical link antenna and a channel characteristic between the measurement environment and the DUT.

5. The computer implemented method of claim 2, wherein the method comprises compensating deviations within a least one characteristic of the antenna characteristic with or without considering a defined metric relating to deviations.

6. The computer implemented method of claim 1, wherein the first beam is a first TX beam generated with the measurement environment that causes the DUT to form an RX beam as the second beam responsive to the first TX beam and to select a second TX beam corresponding to the RX beam and to generate the second TX beam as the third beam.

7. The computer implemented method of claim 1, wherein the beam pair is a first beam pair and wherein the DUT is caused to generate at least one additional beam of at least one additional beam pair, wherein the at least one additional beam is a TX beam or an RX beam.

8. The computer implemented method of claim 1, further comprising pairing the DUT with the measurement environment, such that the pairing comprises a use of electronic markers within an exchange of a signal.

9. The computer implemented method of claim 1, wherein determining the beam correspondence parameter comprises using of an internal parameter of the DUT.

10. The computer implemented method of claim 1, wherein determining the beam correspondence parameter comprises comparing a receive beam pattern indicating a reception performance of the second beam with a transmit beam pattern indicating a transmission performance of the third beam; or comparing a transmit beam pattern indicating a transmission performance of the second beam with a receive beam pattern indicating a reception performance of the third beam. cm 11. The computer implemented method of claim 1, wherein determining the beam correspondence parameter comprises:
instructing the DUT to lock at least one of the second beam and/or the third beam; or causing the DUT to maintain at least one characteristic of the second beam and/or the third beam;
determining a measure related to the second beam and the third beam using the measurement environment and/or the DUT for a plurality of relative positions between the DUT and the measurement environment.

12. The computer implemented method of claim 1, wherein determining the beam correspondence parameter comprises:
comparing a metric related to the second beam of the beam pair and a metric related to the third beam.

13. The computer implemented method of claim 12, wherein the DUT is caused, during an instance of testing, to maintain a TX-beam of a first beam pair and an RX-beam of a second beam pair.

14. The computer implemented method of claim 1, comprising exposing the DUT to a variable or configurable direction of arrival spectrum of multipath components using a link antenna arrangement of the measurement environment.

15. The computer implemented method of claim 1, wherein determining the beam correspondence parameter comprises activating a measurement procedure to determine the receive antenna beam pattern by feeding transmit signals from different directions of the measurement environment consecutively or simultaneously; and
receiving a report from the DUT comprising information related to a direct or indirect reporting and being associated with the signals received at the DUT and/or transmitted by the DUT.

16. The computer implemented method of claim 15, wherein the report relates to antenna test function signals of the DUT.

17. The computer implemented method of claim 1, comprising measuring a transmit beam pattern of the DUT corresponding to a pairing signal of the measurement environment, with the plurality of probes consecutively or simultaneously based on reference signals embedded in a signal transmitted from the DUT, while providing a signal for pairing with a link antenna arrangement or based on providing instructions to the DUT for locking the beam.

18. The computer implemented method of claim 1, comprising:
arranging at least one measurement node of the measurement in a known geometry;
calibrating an exposure to signals for the DUT to acquire a calibrated exposure;
wherein determining the beam correspondence parameter comprises comparing the calibrated exposure with a signal transmitted from the DUT and received with the measurement environment as a response to a signal sent to the DUT.

19. The computer implemented method of claim 1, wherein the DUT is tested in an effective far field, an effective near field and/or using multipath propagation channels.

20. A computer implemented method for determining a phase centre of an antenna arrangement of a DUT, comprising:
causing the DUT to generate a beam with the antenna arrangement;
causing the DUT to lock or maintain at least a part of the beam;
measuring the beam for a plurality of relative directions with respect to the DUT to acquire measurement results; and
evaluating the measurement results to determine the phase centre.

21. The computer implemented method of claim 20, wherein the phase centre is determined for a plurality of beams generated and locked or maintained with the DUT.

22. Measurement environment configured for implementing the computer implemented method of claim 1 or a computer implemented method for determining a phase centre of an antenna arrangement of a DUT, comprising:
causing the DUT to generate a beam with the antenna arrangement;
causing the DUT to lock or maintain at least a part of the beam;
measuring the beam for a plurality of relative directions with respect to the DUT to acquire measurement results; and
evaluating the measurement results to determine the phase centre.

23. A node for a measurement environment comprising:
an interface configured for exchanging a wired signal and an antenna arrangement; and
wherein the node is configured for providing the wired signal based on a wireless signal received with the antenna arrangement and for RX-beamforming for receiving the wireless signal; and/or for providing the wired signal to the antenna arrangement for a transmission based on the wired signal received with the interface and wherein the node is configured for TX-beamforming for transmitting the wireless signal.

24. The node of claim 23, wherein the node is configured for executing a control command to either use the antenna arrangement in a reception mode, in a transmission mode or in a full-duplex mode.

25. The node of claim 23, wherein the node comprises an array unit configured for controlling the antenna arrangement; wherein the node is configured for controlling the array unit so as to variably generate different beam patterns.

26. The node of claim 23, wherein the plurality of antenna elements comprises similar antenna characteristics when receiving the wireless signal and when transmitting the wireless signal;
wherein the antenna elements deviate from a same characteristic by a defined metric.

27. A measurement environment comprising a plurality of nodes according to claim 23.

28. The measurement environment according to claim 27, wherein the plurality of nodes is arranged as at least a part of a Buckyball structure.

29. The measurement environment according to claim 27, wherein the measurement environment is configured for implementing a rotatory movement of the plurality of nodes and/or a translatory movement of the plurality of nodes.

30. The measurement environment according to claim 27, wherein the measurement environment comprises a link antenna arrangement of the measurement environment.

31. The measurement environment according to claim 30, wherein the link antenna arrangement is formed as virtual antenna arrangement implemented by at least one node of the measurement environment.

32. The measurement environment according to claim 27, wherein the measurement environment is configured for executing a computer implemented method according to claim 1 or a computer implemented method for determining a phase centre of an antenna arrangement of a DUT, comprising:
causing the DUT to generate a beam with the antenna arrangement;
causing the DUT to lock or maintain at least a part of the beam;
measuring the beam for a plurality of relative directions with respect to the DUT to acquire measurement results; and
evaluating the measurement results to determine the phase centre.

33. The measurement environment according to claim 27, wherein the measurement environment comprises at least one reflector between a link antenna arrangement and the DUT.

34. A measurement environment comprising a plurality of nodes, each node configured for receiving a signal from the DUT and/or transmitting a signal to the DUT, wherein the measurement environment is adapted to implement a virtual link antenna arrangement using the plurality of nodes.

35. The measurement environment according to claim 34, wherein the measurement environment does not comprise a physical link antenna to pair with a DUT to be tested by use of the nodes.

36. The measurement environment according to claim 34, wherein at least one node is a node for a measurement environment comprising:
an interface configured for exchanging a wired signal and an antenna arrangement; and
wherein the node is configured for providing the wired signal based on a wireless signal received with the antenna arrangement and for RX-beamforming for receiving the wireless signal; and/or for providing the wired signal to the antenna arrangement for a transmission based on the wired signal received with the interface and wherein the node is configured for TX-beamforming for transmitting the wireless signal.
